(19) United States
(12) Patent Application Publication
(10) Pub. No.: US 2025/0133915 A1
(43) Pub. Date: Apr. 24, 2025

(54) DISPLAY PANEL AND DISPLAY DEVICE

(71) Applicants: Hefei Visionox Technology Co., Ltd., Hefei (CN); KunShan Go-Visionox Opto-Electronics Co., Ltd, Kunshan (CN)

(72) Inventors: Yuan YAO, Hefei (CN); Zhenhua LOU, Hefei (CN); Lei ZHANG, Hefei (CN); Bo RAO, Hefei (CN); Jian WU, Hefei (CN); Chen XU, Hefei (CN); Yu JIN, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/912,777

(22) Filed: Oct. 11, 2024

(30) Foreign Application Priority Data
Oct. 19, 2023 (CN) 202311363153.8
Jun. 30, 2024 (CN) 202410864269.8

(51) Int. Cl. H10K 59/122; G06F 3/041; G06F 3/044; H10K 59/35; H10K 59/40

(52) U.S. Cl. CPC H10K 59/122; G06F 3/0412; G06F 3/04164; G06F 3/0443; G06F 3/0446; H10K 59/40; H10K 59/352; H10K 59/353

(57) ABSTRACT

A display panel and a display device, in which the display panel includes an array substrate; a light-emitting layer located on a side of the array substrate and comprising a plurality of light-emitting units that include a plurality of light-emitting unit groups, each of the light-emitting unit groups emitting light of a single color and including at least one light-emitting structure arranged in a first direction; an isolation structure located on a side of the array substrate and comprising an isolation opening, the light-emitting unit is arranged in the isolation opening; and a touch layer comprising touch traces that are arranged on a side of the isolation structure facing away from the array substrate.

### CROSS-REFERENCE TO RELATED APPLICATIONS

This application claims priority to Chinese Patent Application No. 202311363153.8, filed on Oct. 19, 2023, and Chinese Patent Application No. 202410864269.8, filed on Jun. 30, 2024, both of which are hereby incorporated by reference in their entireties.

### TECHNICAL FIELD

The present application relates to the field of display technology, and in particular to a display panel and a display device.

### BACKGROUND

Flat display panels such as Organic Light Emitting Display (OLED) panels and display panels using Light Emitting Diode (LED) devices have the advantages of high image quality, power saving, thin body and wide application range, etc., are widely used in various consumer electronic products such as mobile phones, televisions, personal digital assistants, digital cameras, laptops, desktop computers, etc., and become a mainstream of display devices.

However, some current organic light-emitting diode display panels still have the problem of color shift.

### SUMMARY

The embodiments of the present application provide a display panel and a display device, which can effectively reduce the possibility of color shift of viewing angle.

An embodiment of a first aspect of the present application provides a display panel, which includes an array substrate; a light-emitting layer located on a side of the array substrate and comprising a plurality of light-emitting units that include a plurality of light-emitting unit groups, each of the light-emitting unit groups emitting light of a single color and including at least one light-emitting structure arranged in a first direction; an isolation structure located on a side of the array substrate and comprising an isolation opening, the light-emitting unit is arranged in the isolation opening; and a touch layer comprising touch traces that are arranged on a side of the isolation structure facing away from the array substrate, where at least parts of orthographic projections of the touch traces in a thickness direction of the display panel are arranged around the at least one light-emitting structure, and symmetrically with respect to a first symmetry axis that passes through a centroid of the at least one light-emitting structure and is parallel to the first direction intersecting with the thickness direction.

An embodiment of a second aspect of the present application provides a display panel including a first display area and a second display area, a light transmittance of the first display area is greater than a light transmittance of the second display area, and the display panel further comprising: an array substrate; a light-emitting layer located on a side of the array substrate and comprising a plurality of light-emitting units; an isolation structure located on a side of the array substrate and comprising a plurality of isolation openings and a plurality of through holes, each of the light-emitting units being arranged in the corresponding one of the isolation openings, and the through holes being arranged in the first display area; and a touch layer comprising touch traces that are arranged on a side of the isolation structure facing away from the array substrate, where in the first display area, orthographic projections of the touch traces in a thickness direction of the display panel are arranged at least around the through hole; and in the second display area, orthographic projections of the touch traces in the thickness direction are arranged around the corresponding one of the isolation openings.

An embodiment of a third aspect of the present application provides a display panel comprising: an array substrate; a light-emitting layer located on a side of the array substrate and comprising a plurality of light-emitting units; an isolation structure located on a side of the array substrate and comprising isolation openings, each of the light-emitting units is arranged in the corresponding one of the isolation openings; and a touch layer comprising touch traces that are arranged on a side of the isolation structure facing away from the array substrate, wherein orthographic projections of the touch traces in a thickness direction of the display panel surround an orthographic projection of at least one of the isolation openings in the thickness direction.

### BRIEF DESCRIPTION OF THE DRAWINGS

FIG. 1 is a schematic structural diagram of a top view of a display panel according to an embodiment of the present application;

FIG. 2 is a schematic diagram of an enlarged structure of Q in FIG. 1;

FIG. 3 is a schematic structural cross-sectional view of a display panel according to an embodiment of the present application;

FIG. 4 is a schematic diagram of another enlarged structure of Q in FIG. 1;

FIG. 5 is a schematic diagram of another enlarged structure of Q in FIG. 1;

FIG. 6 is a schematic diagram of another enlarged structure of Q in FIG. 1;

FIG. 7 is a schematic diagram of another enlarged structure of Q in FIG. 1;

FIG. 8 is a schematic diagram of another enlarged structure of Q in FIG. 1;

FIG. 9 is a schematic diagram of another enlarged structure of Q in FIG. 1;

FIG. 10 is a schematic diagram of another enlarged structure of Q in FIG. 1;

FIG. 11 is a schematic diagram of another enlarged structure of Q in FIG. 1;

FIG. 12 is a schematic diagram of another enlarged structure of Q in FIG. 1;

FIG. 13 is a schematic diagram of an enlarged structure of P in FIG. 12;

FIG. 14 is a schematic diagram of another enlarged structure of Q in FIG. 1;

FIG. 15 is a schematic diagram of an enlarged structure of R in FIG. 14;

FIG. 16 is a schematic structural cross-sectional view of another display panel according to in an embodiment of the present application;

FIG. 17 is a schematic structural cross-sectional view of another display panel according to in an embodiment of the present application;

FIG. 18 is a schematic structural cross-sectional view of another display panel according to in an embodiment of the present application;

FIG. 19 is a schematic structural cross-sectional view of another display panel according to in an embodiment of the present application; and

FIG. 20 is a schematic structural diagram of a display panel according to an embodiment of the present application.

### DETAILED DESCRIPTION

In order to improve the preparation accuracy of the light-emitting unit of the display panel, an isolation structure is usually used as an auxiliary structure in the preparation process of the light-emitting unit, and the isolation structure may affect the light-emitting range of the light-emitting unit, especially in the touch display panel. Under the joint influence of the isolation structure and the touch layer, the light-emitting range of the light-emitting unit in different directions will be differentiated, which will cause color shift in displayed images.

Patent Application Nos PCT/CN2023/134518, 202310771071.0, 202311117143.6, 202310759370.2, 202410008807.3, 202310909421.5, and 202311616249.0 record the relevant technical solutions of isolation structure, pixel arrangement, touch control, and array, and their contents are incorporated into this application by reference for reference. Therefore, in order to solve the above problems, in the first aspect, an embodiment of the present application provides a display panel and a display device.

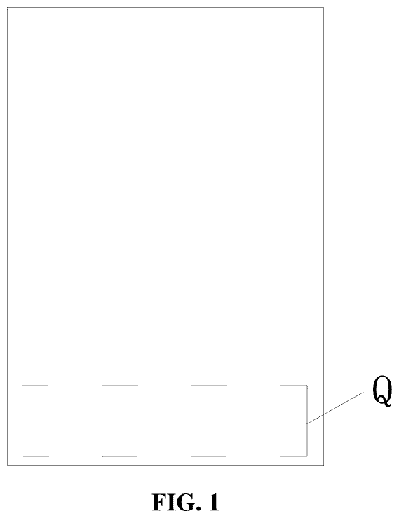

As shown in FIG. 1 to FIG. 3, an embodiment of the present application provides a display panel, which includes an array substrate 10, a light-emitting layer, an isolation structure 20, and a touch layer 40. The light-emitting layer is located on one side of the array substrate 10 and includes a plurality of light-emitting units 30 including a plurality of light-emitting unit groups E0, each of the light-emitting unit groups E0 emitting light of a single color and including at least one light-emitting structure arranged in a first direction X. The isolation structure 20 is located on one side of the array substrate 10 and includes isolation openings 21, the light-emitting unit 30 is arranged in the isolation opening 21. The touch layer 40 includes touch traces 41, which are arranged on a side of the isolation structure 20 facing away from the array substrate 10. At least parts of orthographic projections of the touch traces 41 in a thickness direction Z of the display panel are arranged around at least one light-emitting structure, and symmetrically with respect to a first symmetry axis N1 passing through a centroid of the at least one light-emitting structure. The first symmetry axis N1 is parallel to the first direction X intersecting with the thickness direction Z.

The array substrate 10 can play a supporting and bearing role. Other film layers are stacked on the array substrate 10 in sequence. By the term “stacked” mentioned herein with reference to the arrangement, it is means that other film layers are arranged in sequence in the thickness direction Z of the array substrate 10. Herein, multiple film layer structures may be included in the array substrate 10. The specific film layer structure composition of the array substrate 10 is not limited in the embodiments of the present application. And a thickness direction Z of other film layers located on one side of the array substrate 10 is usually consistent with a thickness direction Z of the array substrate 10 itself. Therefore, for the convenience of expression, the thickness direction Z of the array substrate 10 or the thickness direction Z of other film layers mentioned later in the embodiments of the present application is indicated in the same direction.

The light-emitting layer and the isolation structure 20 are located on the same side of the array substrate 10. The light-emitting layer includes a plurality of light-emitting units 30, which are the main devices for realizing light-emitting display. Herein, the light-emitting units 30 include, but are not limited to, red light-emitting units for emitting red light, green light-emitting units for emitting green light, and blue light-emitting units for emitting blue light. Each light-emitting unit 30 may include a hole inject layer (Hole Inject Layer, HIL), a hole transport layer (Hole Transport Layer, HTL), a light-emitting layer, an electron inject layer (Electron Inject Layer, EIL) and an electron transport layer (Electron Transport Layer, ETL) that are stacked with each other.

The light-emitting unit 30 includes a plurality of light-emitting unit groups E0, and the number of light-emitting structures included in each light-emitting unit group E0 may be the same, or different.

Exemplarily, each light-emitting unit group E0 includes a plurality of light-emitting structures arranged in sequence in the first direction X.

Adjacent light-emitting unit groups E0 may emit light of the same color, or light of different colors.

In some examples, the light-emitting structures in the plurality of light-emitting unit groups E0 may be alternately arranged in the first direction X. Exemplarily, the light-emitting structures in the light-emitting unit group E0 emitting red light and the light-emitting structures in the light-emitting unit group E0 emitting blue light are alternately arranged in the first direction X. In other examples, multiple light-emitting unit groups E0 are arranged in sequence in a single direction or multiple directions.

The isolation opening 21 enclosed by the isolation structure 20 can accommodate the light-emitting unit 30. In other words, the orthographic projection of the light-emitting unit 30 on the array substrate 10 and the orthographic projection of the isolation opening 21 on the array substrate 10 at least partially overlap, and the orthographic projection of the light-emitting unit 30 on the array substrate 10 is at least partially located within the orthographic projection of the isolation opening 21 on the array substrate 10. Further, during the preparation of the light-emitting unit 30, due to the presence of the isolation structure 20, the light-emitting material can be separated into independent light-emitting units 30 by the isolation structure 20, and the precision metal mask evaporation process can be omitted.

For example, taking the preparation of the red light-emitting unit 30 before the preparation of the green light-emitting unit 30 as an example, since the precision metal mask is cancelled, the red light-emitting material corresponding to the red light-emitting unit 30 may first fall into each isolation opening 21, and then the red light-emitting material in part of the isolation opening 21 is selectively etched away, and the red light-emitting material in part of the isolation opening 21 is retained to form the red light-emitting unit 30. After that, the green light-emitting material corresponding to the green light-emitting unit 30 may fall into each isolation opening 21, and then the green light-emitting material in part of the isolation opening 21 is selectively etched away, and the green light-emitting material in part of the isolation opening 21 is retained to form the green light-emitting unit 30.

In embodiments of the present application, the material of the isolation structure 20 includes a conductive material such as a metal or alloy, and the through hole 22 is arranged between adjacent two of the isolation structures 20. The through hole 22 can improve the light transmittance of the display panel to meet the use requirements of the device that needs to be sensitive to light.

Optionally, a shape of an orthographic projection of the isolation opening 21 in the thickness direction Z includes but is not limited to a circle, a square or a rectangle.

The touch layer 40 is arranged on a side of the light-emitting layer away from the array substrate 10, and the touch layer 40 can be configured to realize the touch function. The touch traces 41 are arranged in the display panel, and the touch traces 41 are used to form touch capacitors. After electrically connected to the driving chip, the touch traces 41 exchange functional signals with the driving chip through the touch capacitors to realize the touch function.

In some embodiments, at least parts of the orthographic projections of the touch traces 41 in the thickness direction Z of the display panel are arranged around at least one light-emitting structure. In other words, the orthographic projections of the touch traces 41 in the thickness direction Z can be arranged around one or more light-emitting structures.

Exemplarily, when the orthographic projections of the touch traces 41 in the thickness direction Z are arranged around a light-emitting structure, the orthographic projections of the touch traces 41 in the thickness direction Z are distributed on a periphery of a light-emitting structure, and the touch traces 41 may be in a continuous closed shape or a discontinuous shape. Exemplarily, a figure of the orthographic projections of the touch traces 41 in the thickness direction Z includes a circular ring or a semicircular ring.

Exemplarily, when the orthographic projections of the touch traces 41 in the thickness direction Z are arranged around multiple light-emitting structures, within the range recognizable by the human eye, the multiple light-emitting structures can be regarded as a whole, and the orthographic projections of the touch traces 41 in the thickness direction Z are distributed on a periphery of the whole. The touch traces 41 may be distributed on a periphery of each light-emitting structure. Optionally, there may be one or two touch traces 41 between adjacent two of the light-emitting structures.

The touch traces 41 are symmetrically arranged with respect to the first symmetry axis N1 passing through the centroid of at least one light-emitting structure. In other words, the touch traces 41 are arranged on both sides of the first symmetry axis N1, and because the first symmetry axis N1 passes through the light-emitting structure, the touch traces 41 are arranged on both sides of the light-emitting structure that are symmetrical with respect to the first symmetry axis N1. Optionally, the centroid includes a geometric center. Optionally, the first symmetry axis N1 can pass through the geometric center of the light-emitting structure. Optionally, the first symmetry axis N1 can pass through one light-emitting structure, or the first symmetry axis N1 can pass through multiple light-emitting structures. The touch traces 41 form a grid-shaped touch pattern that includes multiple grids, one grid corresponds to at least one light-emitting structure, and parts of the touch pattern surrounding at least one light-emitting structure are symmetrically arranged with respect to at least the first symmetry axis N1. The “symmetry” mentioned above and in the following text refers to the touch pattern surrounding at least one light-emitting structure.

Optionally, the orthographic projections of the touch traces 41 in the thickness direction Z and the orthographic projections of the isolation structures 20 in the thickness direction Z overlap.

In the display panel provided in the present application, the touch traces 41 are arranged around the isolation opening 21 and symmetrically with respect to the symmetry axis, and the touch traces 41 are arranged on both sides of the light-emitting structure with respect to the symmetry axis, so that the ranges of light emitted from the opposite sides of the light-emitting structure remain the same, thereby reducing the difference in the range of light emitted by the light-emitting unit 30 in the isolation opening 21 in different directions, reducing the difference in the luminous brightness at different positions of the light-emitting unit 30 under a large viewing angle, and reducing the possibility of color shift in displayed images.

In some embodiments, referring to FIGS. 1 to 3, at least one light-emitting structure includes multiple light-emitting structures, and in the light-emitting unit group E0, the multiple light-emitting structures are arranged in sequence in the first direction X.

Exemplarily, a light-emitting unit group E0 includes multiple light-emitting structures, which are arranged in sequence in the first direction X.

In some embodiments, referring to FIGS. 1 to 3, at least parts of the orthographic projections of the touch traces 41 in the thickness direction Z are arranged around the multiple light-emitting structures, and symmetrically with respect to the first symmetry axis N1 passing through the multiple light-emitting structures.

In some examples, a touch trace is arranged around adjacent two of the light-emitting structures, and a part of the touch trace surrounding one of the light-emitting structures surrounds the other light-emitting structure.

Further, the touch traces 41 are symmetrically arranged with respect to the first symmetry axis N1, so that the touch traces 41 are arranged on the two opposite sides of the light-emitting structure in the second direction Y, and optionally, the second direction Y and the first direction X intersect or are arranged perpendicularly.

Optionally, the first symmetry axis N1 passes through all the light-emitting structures in the light-emitting unit group E0, and the first symmetry axis N1 passes through a part of the light-emitting structures in the light-emitting unit group E0.

In these optional embodiments, the above-mentioned arrangements are conducive to simplifying the layout of the touch traces 41, reducing the color shift difference of viewing angle of the display panel in the second direction Y, and improving the display performance of the display panel.

In some embodiments, the touch traces 41 form a grid-shaped touch pattern that includes multiple grids, one grid corresponds to at least one light-emitting structure, and the parts of the touch pattern surrounding at least one light-emitting structure are symmetrically arranged with respect to at least the first symmetry axis.

In some examples, the arrangement of the multiple grids is the same as the arrangement of the multiple isolation openings. In other examples, one grid is arranged around multiple isolation openings, and a light-emitting structure can be arranged in each isolation opening.

The parts of the touch pattern surrounding at least one light-emitting structure are symmetrically arranged with respect to at least the first symmetry axis. In other words, one grid of the touch pattern surrounds one light-emitting unit group, and symmetrical touch traces 41 are arranged on a periphery of one light-emitting unit group in the second direction. The symmetrical touch traces 41 can also be arranged on a periphery of one light-emitting unit group in the first direction or other directions.

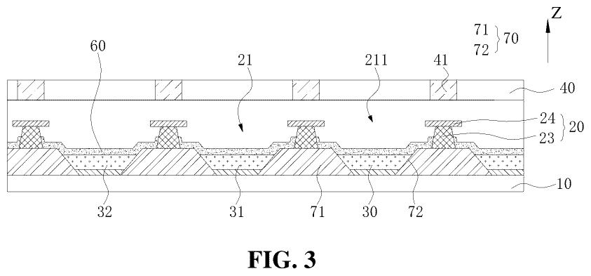

In some optional embodiments, referring to FIGS. 3 to 5, in the light-emitting unit group E0, at least one light-emitting structure includes 2N+1 light-emitting structures, and the orthographic projections of the touch traces 41 in the thickness direction Z are symmetrically arranged with respect to the second symmetry axis N2 parallel to the second direction Y, and passing through a centroid of the N+1th light-emitting structure, where N≥0, and the second direction Y and the first direction X are both perpendicular to the thickness direction Z.

Exemplarily, the light-emitting unit group E0 includes an odd number of light-emitting structures, and the orthographic projections of the touch traces 41 in the thickness direction Z are symmetrically arranged with respect to the second symmetry axis N2, so that the touch traces 41 are arranged on the two opposite sides of the light-emitting structure in the first direction X. Optionally, in the light-emitting unit group E0, the touch traces 41 are arranged on the two opposite sides of each light-emitting structure in the first direction; or, in the light-emitting unit group E0, touch traces 41 are provided on a side of the i-th light-emitting structure facing away from the j-th light-emitting structure, and on a side of the j-th light-emitting structure facing away from the i-th light-emitting structure; or, in the light-emitting unit group E0, touch traces 41 are provided on a side of the first light-emitting structure facing away from the 2N+1-th light-emitting structure, and on a side of the 2N+1-th light-emitting structure facing away from the first light-emitting structure, where 1≤i<j≤2N+1.

Optionally, the light-emitting unit group E0 includes 1, 3, 5, 7 or other odd number of light-emitting structures.

In the embodiments of the present application, through the above arrangement, the touch traces 41 are arranged on the two opposite sides of the light-emitting structure in the first direction X, thereby reducing the color shift difference of the display panel in the first direction X and improving the display performance of the display panel.

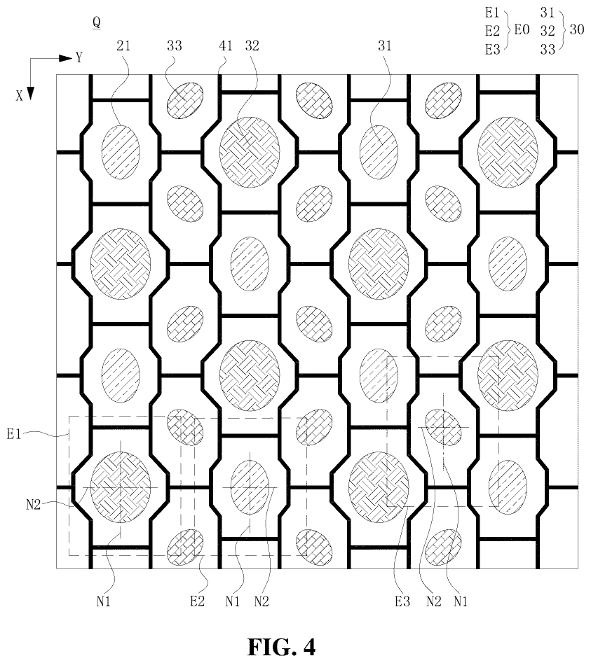

In some optional embodiments, referring to FIG. 3 and FIG. 4, N=0, in the light-emitting unit group E0, at least one light-emitting structure includes a light-emitting structure, and the orthographic projections of the touch traces 41 in the thickness direction Z are symmetrically arranged with respect to the second symmetry axis N2 parallel to the second direction Y and passing through the centroid of the light-emitting structure.

Exemplarily, when the light-emitting unit group E0 includes a light-emitting structure, touch traces 41 are provided on both sides of the light-emitting structure in the first direction X, and on this basis, touch traces 41 are provided on both sides of the light-emitting structure in the second direction Y, so that the orthographic projections of the touch traces 41 in the thickness direction Z surround the periphery of the light-emitting structure, thereby reducing the color shift difference of the viewing angle of the display panel in the first direction X and the second direction Y.

Optionally, the touch traces 41 arranged on both sides of the light-emitting structure in the first direction X and the touch traces 41 arranged on both sides of the light-emitting structure in the second direction Y may be interconnected or disconnected.

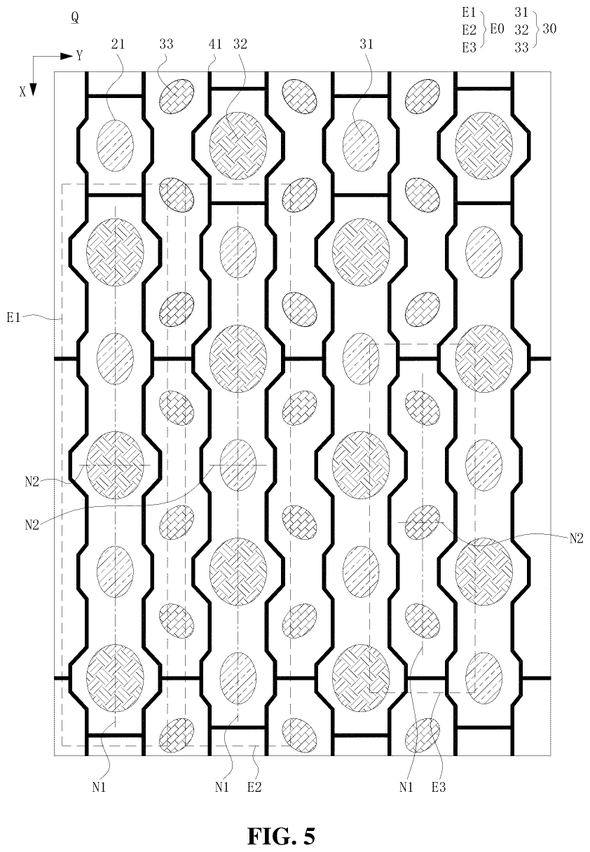

In some optional embodiments, referring to FIG. 3 and FIG. 5, N=1, in the light-emitting unit group E0, at least one light-emitting structure includes three light-emitting structures, and the orthographic projections of the touch traces 41 in the thickness direction Z are symmetrically arranged with respect to the second symmetry axis N2, and the second symmetry axis N2 passing through a centroid of the second light-emitting structure in the first direction X.

Exemplarily, when the light-emitting unit group E0 includes three light-emitting structures, touch traces 41 are provided on both sides of the three light-emitting structures in the second direction Y; or, touch traces 41 are provided on two sides of only the two light-emitting structures at the two ends that face towards or away from each other. On this basis, touch traces 41 are provided on both sides of the light-emitting structure in the second direction Y, so that the orthographic projections of the touch traces 41 in the thickness direction Z surround the periphery of the light-emitting structure, thereby reducing the color shift difference of the viewing angle of the display panel in the first direction X and the second direction Y.

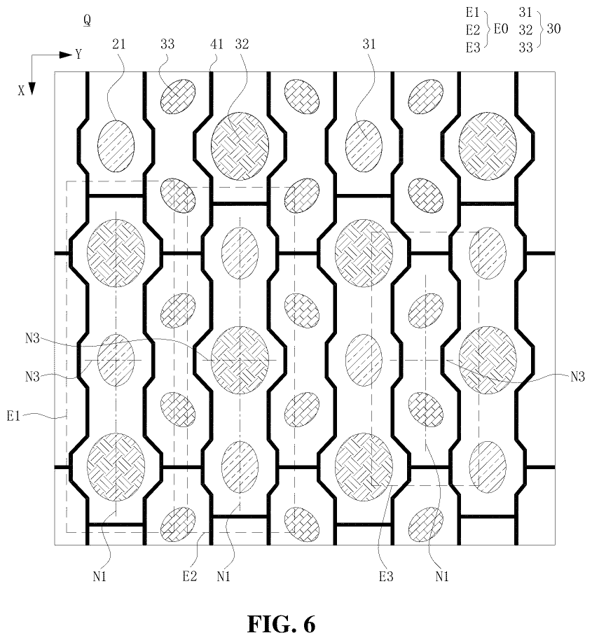

FIG. 6 is a schematic diagram of another enlarged structure of Q in FIG. 1.

In some optional embodiments, referring to FIG. 6, in the light-emitting unit group E0, at least one light-emitting structure includes 2N light-emitting structures, and the orthographic projections of the touch traces 41 in the thickness direction Z are symmetrically arranged with respect to the third symmetry axis N3 parallel to the second direction Y. The third symmetry axis N3 is located between the Nth light-emitting structure and the N+1th light-emitting structure, where N>0, and the second direction Y and the first direction X are both perpendicular to the thickness direction Z.

Exemplarily, the light-emitting unit group E0 includes an even number of light-emitting structures, and the orthographic projections of the touch traces 41 in the thickness direction Z are symmetrically arranged with respect to the third symmetry axis N3, so that the touch traces 41 are arranged on the two opposite sides of the light-emitting structure in the first direction X. Optionally, in the light-emitting unit group E0, the touch traces 41 are arranged on the two opposite sides of each light-emitting structure in the first direction X; or, in the light-emitting unit group E0, touch traces 41 are provided on a side of the i-th light-emitting structure facing away from the j-th light-emitting structure, and on a side of the j-th light-emitting structure facing away from the i-th light-emitting structure; or, in the light-emitting unit group E0, touch traces 41 are provided on a side of the first light-emitting structure facing away from the 2N-th light-emitting structure, and on a side of the 2N-th light-emitting structure facing away from the first light-emitting structure, where 1≤i<j≤2N.

Optionally, the light-emitting unit group E0 includes 2, 4, 6, 8 or other even number of light-emitting structures.

In the embodiments of the present application, through the above-mentioned arrangement, the touch traces 41 are arranged on the two opposite sides of the light-emitting structure in the first direction X, thereby reducing the color shift difference of the display panel in the first direction X and improving the display performance of the display panel.

In some optional embodiments, referring to FIG. 6, N=1, in the light-emitting unit group E0, at least one light-emitting structure includes two light-emitting structures, and the orthographic projections of the touch traces 41 in the thickness direction Z are symmetrically arranged with respect to the third symmetry axis N3, and the third symmetry axis N3 is located in the middle of the first light-emitting structure and the second light-emitting structure.

Exemplarily, when the light-emitting unit group E0 includes two light-emitting structures, the touch traces 41 are provided on both sides of the two light-emitting structures in the second direction Y; or, the touch traces 41 are provided on two sides of only the two light-emitting structures at the two ends that face towards or away from each other. On this basis, touch traces 41 are provided on both sides of the light-emitting structure in the second direction Y, so that the orthographic projections of the touch traces 41 in the thickness direction Z surround the periphery of the light-emitting structure, thereby reducing the difference in the view-angle color shift of the display panel in the first direction X and the second direction Y.

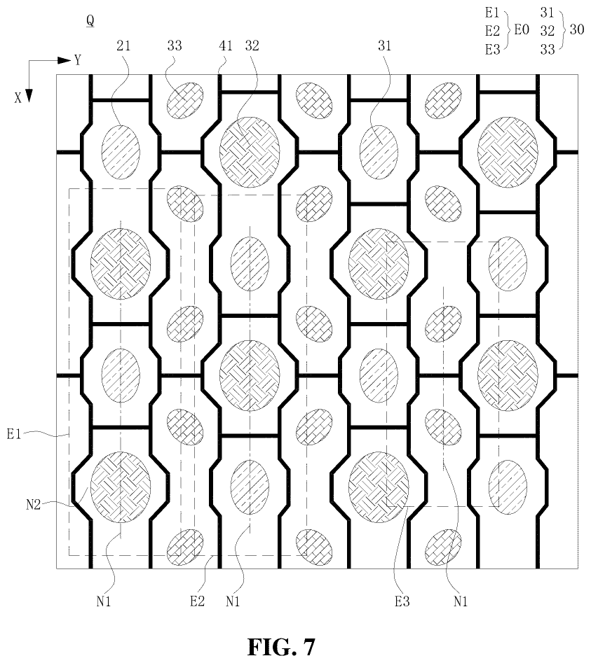

In some optional embodiments, referring to FIG. 7, at least parts of the orthographic projections of the touch traces 41 in the thickness direction Z are arranged around multiple light-emitting structures, and symmetrically with respect to the first symmetry axis N1 parallel to the first direction X and passing through the centroids of multiple light-emitting structures, there is no touch trace 41 provided on the side of the light-emitting structure in the light-emitting unit group E0 at one end of the light-emitting unit group E0 in the first direction X which side is away from the light-emitting structure at the other end of the light-emitting unit group E0 in the first direction X, and there is no touch trace 41 provided on the side of the light-emitting structure in the light-emitting unit group E0 at the other end of the light-emitting unit group E0 in the first direction X which side is away from the light-emitting structure at the one end of the light-emitting unit group E0 in the first direction X.

Exemplarily, the light-emitting unit group E0 includes a plurality of light-emitting structures, touch traces 41 are provided on both sides of each light-emitting structure in the second direction Y, and in the light-emitting unit group E0, there are no touch traces 41 on a side of the first light-emitting structure facing away from the last light-emitting structure and a side of the last light-emitting structure facing away from the first light-emitting structure. The light-emitting structure located at one end of the light-emitting unit group E0 in the first direction X in the light-emitting unit group E0 is the first light-emitting structure, and the light-emitting structure located at the other end of the light-emitting unit group E0 in the first direction X in the light-emitting unit group E0 is the last light-emitting structure.

Optionally, the first direction X and the second direction Y are arranged perpendicularly.

In the embodiments of the present application, the above arrangements are conducive to reducing the space occupied by the touch traces 41 in the touch layer 40, thereby reducing the shielding of light by the touch traces 41 and improving the display brightness of the display panel.

In some optional embodiments, referring to FIG. 4, the orthographic projections of the touch traces 41 in the thickness direction Z enclose the isolation opening 21, and are symmetrically arranged with respect to the first symmetry axis N1 and the second symmetry axis N2, the second symmetry axis N2 is parallel to the second direction Y, and the second direction Y intersects with the first direction X.

Exemplarily, each isolation opening 21 is surrounded by touch traces 41, and the shape of orthographic projections of the touch traces in the thickness direction Z is a continuous closed shape. In addition, the touch traces 41 are symmetrically arranged on both sides of the isolation opening 21 in the first direction X and on both sides of the isolation opening 21 in the second direction Y.

In the embodiments of the present application, by enclosing the isolation opening 21 with the touch traces 41, the range of light emitted by the light-emitting structure in the isolation opening 21 is consistent with the range affected by the touch trace 41 in any direction, thereby reducing the color shift difference under different viewing angles, and further improving the display performance of the display panel.

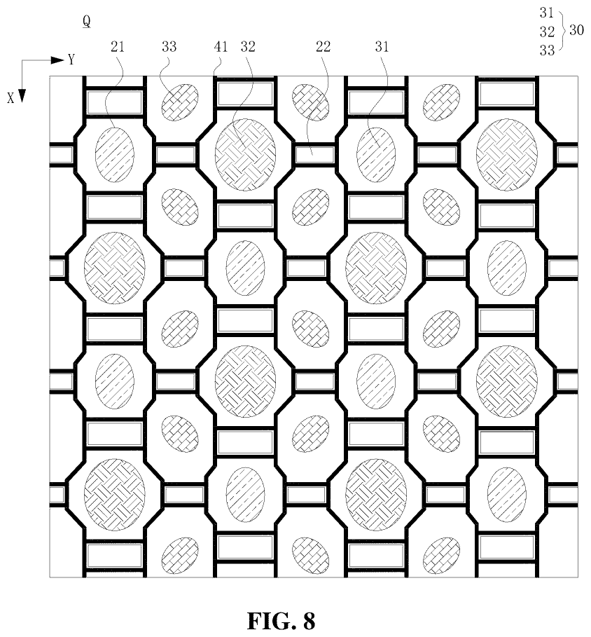

In some optional embodiments, referring to FIG. 8 to FIG. 10, the isolation structure 20 also includes a through hole 22, and a through hole 22 is provided between at least some adjacent two of the isolation openings 21, and the orthographic projections of the touch traces 41 in the thickness direction Z enclose the through hole 22.

Optionally, the orthographic projections of the through hole 22 and the isolation opening 21 in the thickness direction Z can have a similar shape. Of course, they can have different shapes, for example, the shape of orthographic projection of the through hole 22 in the thickness direction Z is a rectangle or a square, and the shape of orthographic projection of the isolation opening 21 in the thickness direction Z is an ellipse.

In some examples, a through hole 22 is provided between every two adjacent isolation openings 21. In other examples, multiple isolation openings 21 include two parts, a through hole 22 is provided between adjacent two of the isolation openings 21 in some parts of the isolation openings 21, and no through hole 22 is provided between adjacent two of isolation openings 21 in the other parts of the isolation openings 21.

The orthographic projections of the touch traces 41 in the thickness direction Z enclose the through hole 22. In other words, a shape of orthographic projections of the touch traces 41 in the thickness direction Z is a continuous closed shape.

The embodiments of the present application improves the light transmittance of the display panel by arranging the through hole 22, and the touch traces 41 enclose the through hole 22, which is conducive to reducing the possibility of the touch traces 41 blocking the through hole 22 from the front, and reducing the difference in the intensity of light received by the photosensitive device through the through hole 22 at different viewing angles.

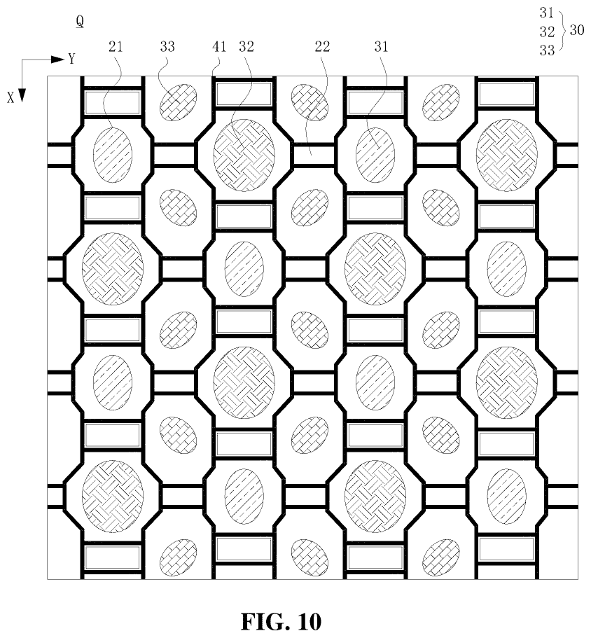

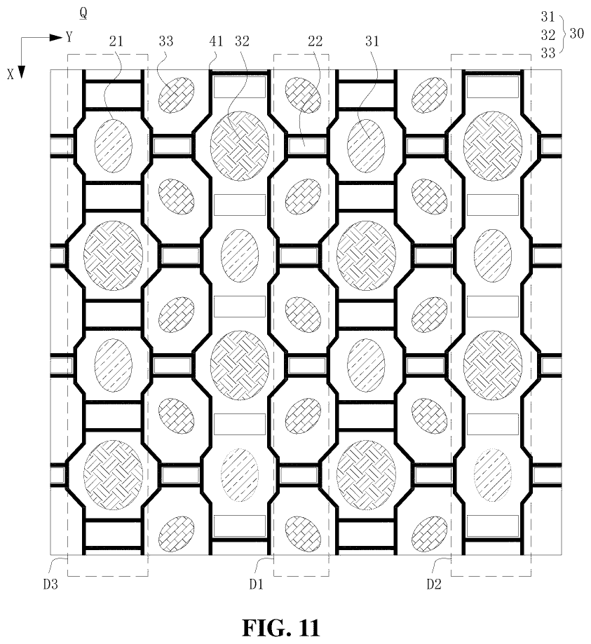

In some optional embodiments, referring to FIGS. 10 and 11, the multiple light-emitting unit groups E0 include a first light-emitting structure group E1 that emits light of a first color, a second light-emitting structure group E2 that emits light of a second color, and a third light-emitting structure group E3 that emits light of a third color, the first light-emitting structure group E1 including at least one first light-emitting structure 31, the second light-emitting structure group E2 including at least one second light-emitting structure 32, and the third light-emitting structure group E3 including at least one third light-emitting structure 33. The light of a first color, the light of a second color, and the light of a third color are different from one another.

Optionally, the light of a first color, the light of a second color and the light of a third color may be red, blue and green, respectively.

Optionally, the first light-emitting structure group E1 may include one or more first light-emitting structures 31. The second light-emitting structure group E2 may include one or more second light-emitting structures 32. The third light-emitting structure group E3 may include one or more third light-emitting structures 33.

In the embodiments of the present application, the first light-emitting structure group E1, the second light-emitting structure group E2 and the third light-emitting structure group E3 are arranged, and the touch traces 41 are arranged around the first light-emitting structure group E1, the second light-emitting structure group E2 and the third light-emitting structure group E3, which is conductive to reducing the color shift difference of light of different colors at different viewing angles and improving the display performance of the display panel.

In some optional embodiments, referring to FIG. 10 and FIG. 11, the first light-emitting structure 31 and the second light-emitting structure 32 are alternately arranged in the first direction X to form a first light-emitting column, the third light-emitting structures 33 are sequentially arranged in the first direction X to form a second light-emitting column, the first light-emitting column and the second light-emitting column are alternately arranged in the second direction Y, and the first light-emitting structure 31 of one of two adjacent columns of the first light-emitting columns and the second light-emitting structure 32 of the other of the two adjacent columns of the first light-emitting columns are sequentially arranged in the second direction Y.

Exemplarily, the first light-emitting columns are provided on both sides of the second light-emitting column in the second direction Y, and the two first light-emitting columns are the first first light-emitting column and the second first light-emitting column. In some examples, the first light-emitting structure 31 in the first first light-emitting column and the first light-emitting structure 31 in the second first light-emitting column are arranged oppositely in the second direction Y. The second light-emitting structure 32 in the first first light-emitting column and the second light-emitting structure 32 in the second first light-emitting column are arranged oppositely in the second direction Y. In other examples, the first light-emitting structure 31 in the first first light-emitting column and the second light-emitting structure 32 in the second first light-emitting column are arranged oppositely in the second direction Y. The second light-emitting structure 32 in the first first light emitting column and the first light-emitting structure 31 in the second first light-emitting column are arranged oppositely in the second direction Y. Here, “arranged oppositely” means that the line connecting the geometric centers of the two light-emitting structures is parallel to the second direction Y.

Further, the third light-emitting structure 33 in the second light-emitting column is correspondingly located between the first light-emitting structure 31 and the second light-emitting structure 32 that are adjacent in the first light-emitting column.

In some examples, a plane parallel to the thickness direction Z and perpendicular to the second direction Y is a first plane, and the orthographic projection of the third light-emitting structure 33 in the second light-emitting column on the first plane is located between the orthographic projection of the first light-emitting structure 31 in the first light-emitting column and the orthographic projection of the second light-emitting structure 32 in the first plane.

Exemplarily, the midpoint of the line connecting the geometric centers of the first light-emitting structures 31 and the second light-emitting structure 32 that are adjacent in the first light-emitting column and the line connecting the geometric center of the third light-emitting structure 33 are parallel to the second direction Y.

The above-mentioned arrangements of the embodiments of the present application are conducive to improving the space utilization rate of the light-emitting structure in the display panel and improving the pixel density.

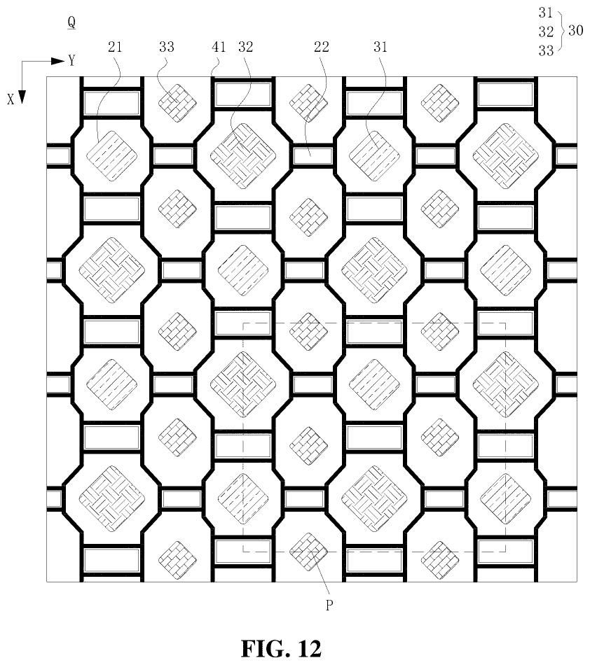

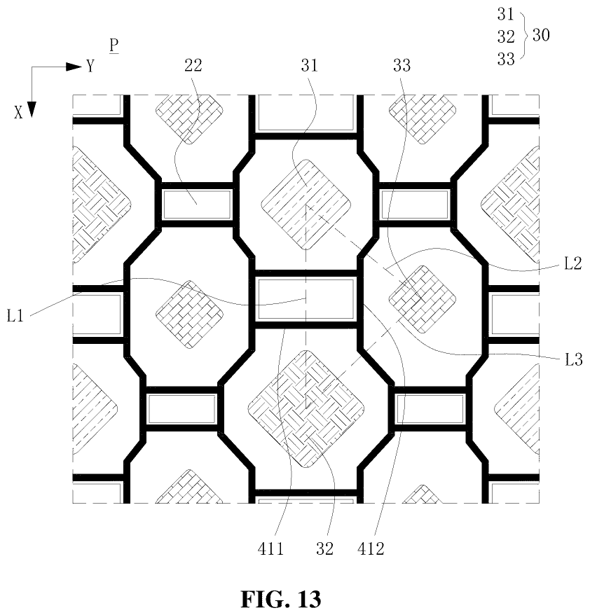

In some optional embodiments, referring to FIG. 12 and FIG. 13, the light-emitting layer includes a plurality of pixel units arranged repeatedly, the pixel units taking the form of a plurality of virtual quadrilaterals arranged in rows and columns, two vertices of the virtual quadrilateral opposite in the first direction X coinciding with the centers of a first light-emitting structure 31 and a second light-emitting structure 32 respectively, and the other two vertices opposite in the second direction Y coinciding with the centers of two third light-emitting structures 33 respectively, and the first direction X and the second direction Y are arranged perpendicularly.

Optionally, a plurality of pixel units are arranged in an array in the first direction X and the second direction Y.

Exemplarily, the geometric centers of a first light-emitting structure 31 and a second light-emitting structure 32 are arranged oppositely in the first direction X, the geometric centers of the two third light-emitting structures 33 are arranged oppositely in the second direction Y, and the four geometric centers of a first light-emitting structure 31 and a second light-emitting structure 32 and two third light-emitting structures 33 form four vertices of the virtual quadrilateral.

In the embodiments of the present application, the light-emitting structures in the pixel unit are arranged according to the vertices of the virtual quadrilateral, which is conducive to simplifying the overall structure of the pixel unit, improving the arrangement shape of the pixel unit, and improving the applicability of the display panel.

In some optional embodiments, the shapes of the first light-emitting structure 31, the second light-emitting structure 32 and the third light-emitting structure 33 include one or more combinations of circular, rectangular and elliptical shapes, which is conducive to increasing the arrangement of the light-emitting structure and improving the application range of the display panel.

Optionally, the shape of the first light-emitting structure 31 includes one or more combinations of circular, rectangular, rhombus and elliptical shapes.

Optionally, the shape of the second light-emitting structure 32 includes one or more combinations of circular, rectangular, rhombus and elliptical shapes.

Optionally, the shape of the third light-emitting structure 33 includes one or more combinations of circular, rectangular, rhombus and elliptical shapes.

Optionally, the shapes of the first light-emitting structure 31, the second light-emitting structure 32 and the third light-emitting structure 33 may be the same, and the areas may be the same or different. For example, the areas of the light-emitting structures corresponding to light of different colors are different.

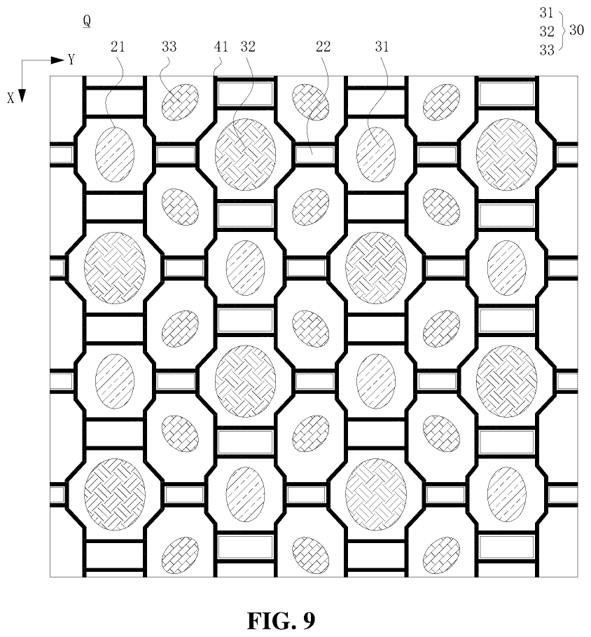

In some optional embodiments, referring to FIG. 9 and FIG. 10, a through hole 22 is provided between adjacent two of isolation openings 21 in one of the first light-emitting column and the second light-emitting column.

In some examples, a through hole 22 is provided between adjacent two of the isolation openings 21 in the first light-emitting column. In other examples, a through hole 22 is provided between adjacent two of the isolation openings 21 in the second light-emitting column.

In the embodiments of the present application, through the above-mentioned arrangement, the through hole 22 can be arranged according to different design requirements to meet different light transmission requirements.

In some optional embodiments, referring to FIG. 9, the through hole 22 is provided in one of the two adjacent first light-emitting columns.

Exemplarily, two first light-emitting columns are provided on both sides of the second light-emitting column in the second direction Y, and the two first light-emitting columns may be the first first light-emitting column and the second first light-emitting column. In some examples, a through hole 22 is provided between adjacent two of the isolation openings 21 in the first first light-emitting column. In other examples, a through hole 22 is provided between adjacent two of the isolation openings 21 in the second first light-emitting column.

In some optional embodiments, referring to FIG. 11, the light-emitting units 30 include a first type of light-emitting column D1, a second type of light-emitting column D2, and a third type of light-emitting column D3, and a through hole 22 is provided between adjacent two of the isolation openings 21 in the first type of light-emitting column D1 and the second type of light-emitting column D2. In the first type of light-emitting column D1, the isolation opening 21 and the through hole 22 are separately surrounded by the orthographic projections of the touch traces 41 in the thickness direction Z. In the second type of light-emitting column D2, the isolation opening 21 and the through hole 22 are jointly surrounded by the orthographic projections of the touch traces 41 in the thickness direction Z. In the third type of light-emitting column D3, multiple isolation openings 21 are jointly surrounded by the orthographic projections of the touch traces 41 in the thickness direction Z.

Optionally, the first type of light-emitting column D1, the second type of light-emitting column D2 and the third type of light-emitting column D3 may be the first light-emitting column or the second light-emitting column.

In the first type of light-emitting column D1 and the second type of light-emitting column D2, a through hole 22 is provided between adjacent two of the isolation openings 21. In the third type of light-emitting column D3, a through hole 22 may or may not be provided between adjacent two of the isolation openings 21.

In the first type of light-emitting column D1, the orthographic projections of the touch traces 41 in the thickness direction Z surround the isolation opening 21 and the through hole 22 separately. In other words, in the first type of light-emitting column D1, there are touch traces 41 provided around the isolation opening 21, and there are touch traces 41 provided around the through hole 22.

In the second type of light-emitting column D2, the isolation opening 21 and the through hole 22 are jointly surrounded by the orthographic projections of the touch traces 41 in the thickness direction Z. In other words, in the second type of light-emitting column D2, there is no touch trace 41 between the isolation opening 21 and the through hole 22, and the touch traces 41 can be arranged on the remaining periphery of the isolation opening 21 and on the remaining periphery of the through hole 22. Here, the “remaining periphery” refers to a periphery of the isolation opening 21 except a side between the isolation opening 21 and the through hole 22, and a periphery of the through hole 22 except a side between the isolation opening 21 and the through hole 22.

In the third type of light-emitting column D3, a plurality of isolation openings 21 are jointly surrounded by the orthographic projections of the touch traces 41 in the thickness direction Z. In other words, in the third type of light-emitting column D3, no touch trace 41 is arranged between the isolation openings 21, and the touch trace 41 may be arranged on the remaining peripheries of the isolation openings 21. The “remaining peripheries” here refer to the peripheries of the isolation openings 21 except a side between the isolation opening 21 and the isolation opening.

In these optional embodiments, the first type of light-emitting column D1, the second type of light-emitting column D2 and the third type of light-emitting column D3 can be arranged in a targeted manner according to design requirements, so as to improve the local brightness in a targeted manner to reduce the color shift difference under different viewing angles and improve the display effect of the display panel.

In some optional embodiments, referring to FIGS. 12 and 13, the first light-emitting structure 31, the second light-emitting structure 32 and the third light-emitting structure 33 each are in a rectangular shape. In the first light-emitting column, the vertex angles of the first light-emitting structure 31 and the vertex angles of the second light-emitting structure 32 are arranged oppositely in the first direction X, and in the second light-emitting column, the vertex angles of adjacent two of the third light-emitting structures 33 are arranged oppositely in the first direction X; herein the through hole 22 is arranged between the first light-emitting structure 31 and the second light-emitting structure 32 that are adjacent in the first light-emitting column; and/or, the through hole 22 is arranged between adjacent two of the third light-emitting structures 33 in the second light-emitting column.

In some examples, the through hole 22 is arranged between the first light-emitting structure 31 and the second light-emitting structure 32 that are adjacent in the first light-emitting column. In other examples, the through hole 22 is arranged between adjacent two of the third light-emitting structures 33 in the second light-emitting column. In some other examples, the through hole 22 is arranged between the first light-emitting structure 31 and the second light-emitting structure 32 that are adjacent in the first light-emitting column. In addition, the through hole 22 is arranged between adjacent two of the third light-emitting structures 33 in the second light emitting column.

In these optional embodiments, the light-emitting structure is arranged to a rectangle and the vertex angles of adjacent light-emitting structures in the same column are arranged oppositely, so as to short the spacing distance of the light-emitting structures in the second direction Y, thereby improving the pixel density and the display effect of the display panel.

In some optional embodiments, referring to FIGS. 12 and 13, the touch traces 41 around the through hole 22 are in a rectangular shape, and the vertex angles of any one of the first light-emitting structure 31, the second light-emitting structure 32 and the third light-emitting structure 33 are arranged oppositely to the opposite sides of the touch traces 41 surrounding the through hole 22.

Exemplarily, the vertex angles of the first light-emitting structure 31 are arranged oppositely to the opposite sides of the touch traces 41 surrounding the through hole 22. The vertex angles of the second light-emitting structure 32 are arranged oppositely to the opposite sides of the touch traces 41 surrounding the through hole 22. The vertex angles of the third light-emitting structure 33 are arranged oppositely to the opposite sides of the touch traces 41 surrounding the through hole 22.

The above arrangements of the embodiment in the present application are conducive to reducing the range of light emitted through the vertex angles, so as to improve the uniformity of the light intensity emitted via the vertex angles and the light intensity emitted via the opposite sides.

In some optional embodiments, referring to FIGS. 12 and 13, the orthographic projections of the touch traces 41 in the thickness direction Z are arranged around a periphery of the isolation opening 21 and a periphery of the through hole 22, and a touch trace 41 includes a first section 411 and a second section 412, the orthographic projections of the first section and the second section in the thickness direction Z jointly surround the through hole 22 between adjacent two of the isolation openings 21, a center line connecting adjacent two of the light-emitting structures is perpendicular to the first section 411 and parallel to the second section 412.

Optionally, the shape of the through hole 22 is a rectangle, and the shape formed by the first sections 411 and the second sections 412 is a rectangle. Optionally, the number of first sections 411 is two, and the number of second sections 412 is two.

Exemplarily, the first section 411 of the touch trace 41 and the line connecting the geometric centers of adjacent two of the light-emitting structures are arranged perpendicularly, and the second section 412 of the touch trace 41 and the line connecting the geometric centers of adjacent two of the light-emitting structures are arranged in parallel. Here, “adjacent two of the light-emitting structures” refer to the light-emitting structures adjacent to the first section 411.

In some optional embodiments, referring to FIGS. 12 and 13, a plurality of light-emitting structures are arranged in columns in the first direction X and in rows in the second direction Y. In the same column, the center line connecting adjacent two of the light-emitting structures is arranged perpendicularly to the first section 411, the center line connecting adjacent two of the light-emitting structures is parallel to the second section 412, and the center line connecting any one of the first light-emitting structure 31 and the second light-emitting structure 32 in the first light-emitting column with the third light-emitting structure 33 in the second light-emitting column is arranged perpendicularly to the touch trace 41 between the first light-emitting structure 31 and the third light-emitting structure 33 or the touch trace 41 between the second light-emitting structure 32 and the third light-emitting structure 33.

Optionally, in the same column, the center line connecting adjacent two of the light-emitting structures is a first connection line L1, a center line connecting the first light-emitting structure 31 in the first light-emitting column with the third light-emitting structure 33 in the second light-emitting column is a second connection line L2, and a center line connecting the second light-emitting structure 32 in the first light-emitting column with the third light-emitting structure 33 in the second light-emitting column is a third connection line L3.

Exemplarily, the first connection line L1 is perpendicular to the first sections 411.

Exemplarily, the second connection line L2 is perpendicular to a touch trace 41 between the first light-emitting structure 31 and the third light-emitting structure 33.

Exemplarily, the third connection line L3 is perpendicular to a touch trace 41 between the second light-emitting structure 32 and the third light-emitting structure 33.

In these optional embodiments, the above-mentioned arrangements are conducive to simplifying the arrangement method of the touch traces 41, reducing the difficulty of arranging the touch traces 41, and improving the production efficiency of the display panel.

In some optional embodiments, referring to FIG. 13, a spacing distance between one of adjacent two of the isolation openings 21 and the through hole 22 is equal to a spacing distance between the other of adjacent two of the isolation openings 21 and the through hole, and the orthographic projections of the touch traces 41 in the thickness direction Z are arranged around the periphery of the through hole 22.

Exemplarily, a through hole 22 is arranged between adjacent two of the isolation openings 21, the two isolation openings 21 are a first isolation opening 21 and a second isolation opening 21, the spacing distance between the first isolation opening and the through hole 22 is equal to the spacing distance between the second isolation opening 21 and the through hole 22, and the orthographic projections of the touch traces 41 in the thickness direction Z are arranged around the periphery of the through hole 22, so as to reduce the influence of the touch traces 41 on the light transmission performance of the through hole 22, and improve the color shift difference of different isolation openings 21 at different viewing angles.

In some optional embodiments, referring to FIG. 3 and FIG. 4, the isolation structure 20 includes a first isolation part 23 and a second isolation part 24 located on a side of the first isolation part away from the substrate, and the second isolation parts 24 enclose and form isolation sub-openings 211; the first light-emitting structure 31 and the second light-emitting structure 32 are arranged adjacent to each other, the orthographic projections of the touch traces 41 in the thickness direction Z each are located between adjacent of the first light-emitting structure 31 and the second light-emitting structure 32, and a spacing distance between the inner wall of the isolation sub-opening 211 located on a side of the first light-emitting structure 31 close to the second light-emitting structure 32 and the orthographic projection of the touch trace 41 in the thickness direction Z is equal to a spacing distance between an inner wall of the isolation sub-opening 211 located on a side of the second light-emitting structure 32 close to the first light-emitting structure 31 and the orthographic projection of the touch trace 41 in the thickness direction Z.

Exemplarily, the first isolation part 23 and the second isolation part 24 jointly enclose and form the isolation opening 21, and the second isolation parts 24 enclose and form the isolation sub-openings 211.

An inner wall of the isolation sub-opening 211 located on one side of the first light-emitting structure 31 close to the second light-emitting structure 32 is a side wall of the second isolation part 24 enclosing the first light-emitting structure 31 that is located on the side close to the second light-emitting structure 32. Optionally, this side wall may be a first side wall. An inner wall of the isolation sub-opening 211 located on one side of the second light-emitting structure 32 close to the first light-emitting structure 31 is a side wall of the second isolation part 24 enclosing the second light-emitting structure 32 that is located on the side close to the first light-emitting structure 31. Optionally, this side wall may be a second side wall. A spacing distance between the first side wall and the orthographic projection of the touch trace 41 in the thickness direction Z is equal to a spacing distance between the second side wall and the orthographic projection of the touch trace 41 in the thickness direction Z, so as to reduce the number of touch traces 41 arranged between adjacent two of the light-emitting structures, thereby reducing the influence of the touch traces 41 on the light-emitting structures.

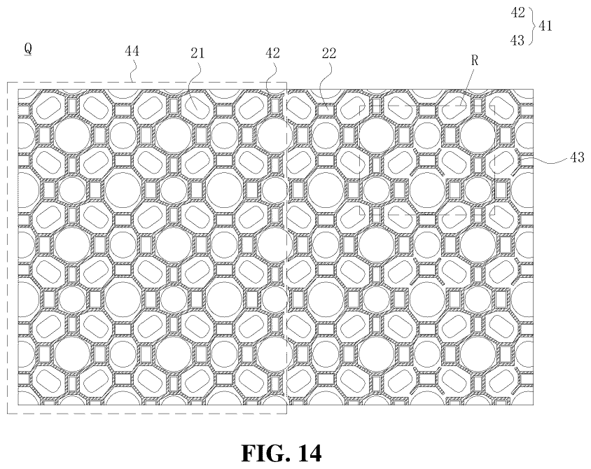

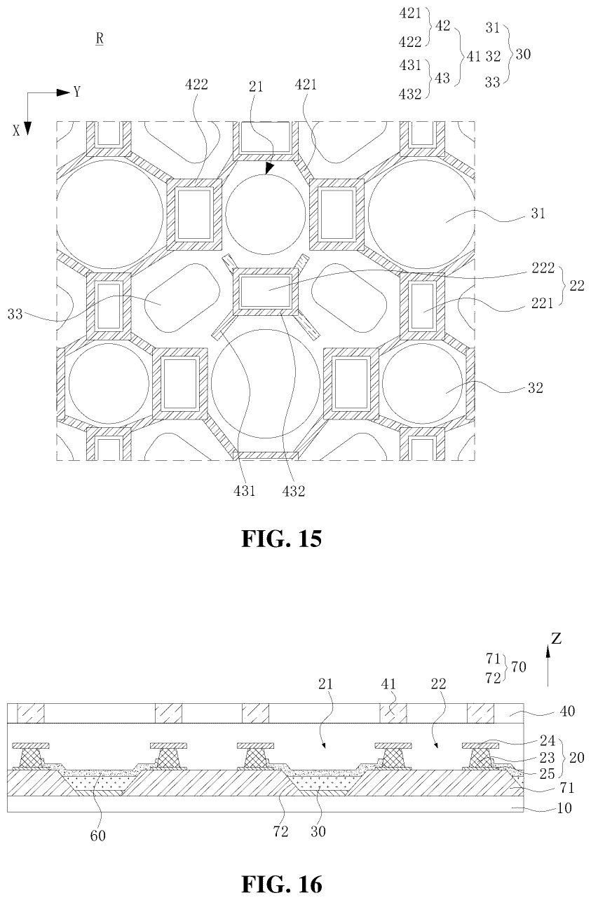

In some optional embodiments, referring to FIG. 14 and FIG. 15, a touch trace 41 includes a touch conductive part 42 and a virtual conductive part 43, and a plurality of touch conductive parts are electrically connected to each other to form a touch electrode 44, and the virtual conductive parts 43 and the touch conductive parts 42 are arranged at intervals.

In the embodiments of the present application, the touch electrode 44 includes a sensing electrode and a transmitting electrode, and the plurality of touch conductive parts 42 may include two parts, a part of the touch conductive part 42 forms a sensing electrode, and a part of the touch conductive part 42 forms a transmitting electrode, and the two parts of the touch conductive part 42 are insulated and arranged adjacent to each other.

In some embodiments, the virtual conductive part 43 may be arranged in the touch electrode 44. In other words, the virtual conductive part 43 may be arranged in the sensing electrode, and the virtual conductive part 43 may be arranged in the emitting electrode. By arranging the virtual conductive part 43 in the touch electrode 44, the parasitic capacitance generated by the touch electrode and other conductive film layers can be reduced, thereby reducing the influence of the parasitic capacitance on the touch function. In addition, the arrangement of the virtual conductive part 43 can also reduce the difference in the ranges of light emitted by the light-emitting unit 30 from different viewing angles, thereby reducing the possibility of color shift occurred in the displayed images.

In some optional embodiments, referring to FIG. 15, the touch conductive part 42 includes a first sub-part 421 and a second sub-part 422, the first sub-part is located on at least one side of the isolation opening 21, and an orthographic projection of the second sub-part 422 in the thickness direction Z surrounds an orthographic projection of the through hole 22 in the thickness direction Z and is connected to the first sub-part 421.

Optionally, second sub-parts 422 of adjacent two of the through holes 22 may be connected through the first sub-part 421.

The orthographic projection of the first sub-part 421 in the thickness direction Z is located on at least one side of the orthographic projection of the isolation opening 21 in the thickness direction Z. Taking as an example that the shape of orthographic projection of the isolation opening is a circle, the first sub-part 421 may be located on one side of the isolation opening 21 in the first direction X, or the first sub-part 421 may be located on one side of the isolation opening 21 in the second direction Y, or the first sub-part 421 may be arranged around the isolation opening 21. The first sub-part blocks the light emitted by the light-emitting unit 30 in the isolation opening. The first sub-part 421 can be arranged on a periphery of the isolation opening 21 according to design requirements, so that the range of light emitted by the light-emitting unit 30 meets different design requirements.

The orthographic projection of the second sub-part 422 in the thickness direction Z is arranged around the orthographic projection of the through hole 22 in the thickness direction Z, thereby reducing the possibility of the second sub-part 422 blocking the through hole 22, and further improving the light transmittance of the through hole; the first sub-part 421 and the second sub-part 422 are connected to increase the effective area of the touch electrode 44 formed by the touch conductive part 42, so as to improve the touch sensitivity.

In some embodiments, referring to FIG. 14 and FIG. 15, the orthographic projections of the first sub-parts 421 and the second sub-parts 422 in the thickness direction Z are arranged to jointly surround the orthographic projection of the isolation opening 21.

In the embodiments of the present application, the second sub-part 422 is not only arranged around the through hole 22, but at least part of the second sub-part is also located between the through hole 22 and the isolation opening 21. The orthographic projections of the first sub-part 421 and the second sub-part 422 are arranged to jointly surround the orthographic projection of the isolation opening 21, thereby reducing the difficulty of arranging the touch traces 41 and further reducing the difference in the ranges of light emitted by the light-emitting unit 30 at different viewing angles.

Optionally, the shape of orthographic projection of the second sub-part 422 may be, but is not limited to, annular, semi-annular or strip-shaped.

In some embodiments, referring to FIG. 14 and FIG. 15, the virtual conductive part 43 includes a third sub-part 431 and a fourth sub-part 432. The fourth sub-part is arranged around at least one through hole 22. The third sub-part 431 is connected to the fourth sub-part 432 and extends away from the inner part of the fourth sub-part.

In the embodiments of the present application, the third sub-part 431 extends away from the inner part of the fourth sub-part 432. In other words, taking as an example that the shape of the orthographic projection of the fourth sub-part 432 in the thickness direction Z is a rectangle, the third sub-part 431 may be arranged to extend from the side edges of the rectangle away from the inner part of the fourth sub-part 432, and the third sub-part 431 may be arranged to extend from one side or vertex angle of the rectangle away from the inner part of the fourth sub-part 432. Of course, in other examples, the shape of the orthographic projection of the fourth sub-part 432 in the thickness direction Z may also include a circle, a square, a triangle or other shapes.

Optionally, fourth sub-parts 432 of adjacent two of the through holes 22 may be connected by the third sub-part 431.

The orthographic projection of the third sub-part 431 in the thickness direction Z is located on at least one side of the orthographic projection of the isolation opening 21 in the thickness direction Z. Taking as an example that the shape of orthographic projection of the isolation opening is a circle, the third sub-part 431 can be located on one side of the isolation opening 21 in the first direction X, or the third sub-part 431 can be located on one side of the isolation opening 21 in the second direction Y, or the third sub-part 431 can be arranged around the isolation opening 21. The third sub-part blocks the light emitted by the light-emitting unit 30 in the isolation opening. The third sub-part 431 can be arranged on the periphery of the isolation opening 21 according to design requirements, so that the range of light emitted by the light-emitting unit 30 meets different design requirements.

The orthographic projection of the fourth sub-part 432 in the thickness direction Z is arranged around the orthographic projection of the through hole 22 in the thickness direction Z, thereby reducing the possibility of the fourth sub-part 432 blocking the through hole 22, thereby improving the light transmittance of the through hole.

In some embodiments, referring to FIG. 15, the fourth sub-part 432 is connected to multiple third sub-parts 431 arranged at intervals.

Optionally, the multiple third sub-parts 431 connected to the fourth sub-part 432 may be arranged between different isolation openings 21 respectively. Of course, at least part of the multiple third sub-parts 431 connected to the fourth sub-part 432 may be located between the same adjacent two of the isolation openings 21.

As an example, a plurality of isolation openings 21 are distributed on the periphery of the through hole 22, and the number of the multiple third sub-parts 431 connected to the fourth sub-part 432 is equal to the number of the multiple isolation openings 21 distributed on the periphery of the through hole 22 enclosed by the fourth sub-part 432.

In the embodiments of the present application, by arranging a plurality of third sub-parts 431 connected to the fourth sub-part 432, the space occupied by the virtual electrode in the touch electrode 44 can be increased, and the possibility of parasitic capacitance generated by the touch electrode and other conductive film layers can be further reduced. In addition, the plurality of third sub-parts 431 can effectively balance the difference in the ranges of light emitted by the light-emitting unit 30 at different viewing angles.

In some optional embodiments, referring to FIG. 3, the isolation structure 20 includes a first isolation part 23 and a second isolation part 24 located on a side of the first isolation part away from the substrate, and the orthographic projection of the first isolation part 23 on the substrate is located within the orthographic projection of the second isolation part 24 on the substrate.

Optionally, the orthographic projection of the touch trace 41 in the thickness direction Z and the orthographic projection of the second isolation part 24 in the thickness direction Z at least partially overlap.

A light-emitting unit 30 and a first electrode 60 may be formed in the isolation opening 21, the first electrode is located on a side of the light-emitting unit 30 facing away from the array substrate 10, the first electrode 60 can be electrically connected to the isolation structure 20, and the first electrode 60 can realize signal exchange between the isolation structure 20 and the driving chip. Optionally, the first electrode 60 includes a cathode.

The specific size and shape of the first isolation part 23 and the second isolation part 24 are not limited in the embodiments of the present application. Exemplarily, the longitudinal cross-section of the isolation structure 20 may be larger at a top and smaller at a bottom. This design is conductive to enabling it difficult for the light-emitting material and the electrode material to extend along the side wall of the first isolation part 23 to the side wall of the second isolation part 24 during the preparation of the light-emitting unit 30 and the first electrode 60, so that the light-emitting units 30 and the first electrodes 60 in different isolation openings 21 can be prepared and separated from each other without the need for a fine metal mask.

The embodiments of the present application do not limit the material compositions of the first isolation part 23 and the second isolation part 24. The first isolation part 23 and the second isolation part 24 can both include conductive materials, or the first isolation part 23 includes conductive materials, and the second isolation part 24 includes insulating materials, as long as the two electrodes can achieve signal transmission with the help of the isolation structure 20.

In some embodiments, referring to FIG. 16, the isolation structure 20 also includes a third isolation part 25, and the first isolation part 23 is located between the third isolation part and the second isolation part 24.

The isolation structure 20 at least includes a first isolation part 23, a second isolation part 24, and a third isolation part 25. The embodiments of the present application do not limit the sizes and shapes of the first isolation part 23, the second isolation part 24, and the third isolation part 25. Exemplarily, the orthographic projection of the first isolation part 23 on the array substrate 10 is located within the orthographic projection of the third isolation part 25 on the array substrate, that is, the longitudinal cross-sections of the first isolation part 23, the second isolation part 24 and the third isolation part 25 each are in an I-shaped shape.

Similar to the first isolation part 23, the third isolation part 25 also includes a conductive material, and the first electrode 60 can directly contact the third isolation part 25 to achieve electrical connection with the first isolation part 23 by means of the third isolation part. Optionally, the first electrode 60 and the third isolation part 25 overlap. Further, the first electrode 60 can be partially located on the side of the third isolation part 25 away from the array substrate 10, and the arrangement of the third isolation part is conductive to improving the reliability of the electrical connection between the first electrode 60 and the isolation structure 20. For example, the first isolation part 23 is made of aluminum material, the second isolation part 24 is made of titanium material, and the third isolation part 25 is made of molybdenum material.

In some embodiments, referring to FIG. 16, the display panel further includes pixel definition layers 70, the pixel definition layers 70 are provided on the array substrate 10, the pixel definition layers include pixel definition parts 71 and pixel openings 72 defined by the pixel definition parts, the pixel openings are connected with the isolation openings 21 to accommodate the light-emitting units 30, and the orthographic projection of the inner wall of each of pixel openings 72 on the substrate is located within the orthographic projection of the inner wall of each of isolation openings 21 on the array substrate 10.

The pixel definition layers 70 include pixel defining parts 71 and pixel openings 72. The pixel openings are arranged corresponding to the isolation openings 21. Exemplarily, the orthographic projection of the pixel opening 72 on the array substrate 10 may be located within the orthographic projection of the isolation opening 21 on the array substrate 10, and the light-emitting unit 30 and a part of structure in the first electrode 60 may be located within the pixel opening 72.

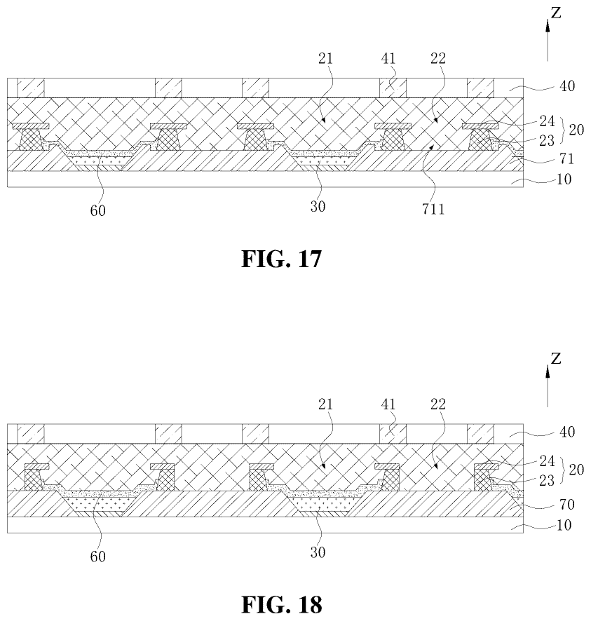

In some embodiments, referring to FIGS. 16 and 17, the isolation structure 20 is arranged on a side of the pixel defining part 71 away from the array substrate 10, or the pixel defining part 71 is provided with a receiving groove 711, and the isolation structure 20 is arranged in the receiving groove.

The isolation structure is arranged on a side of the pixel defining part 71 away from the array substrate 10, that is, the orthographic projection of the isolation structure 20 on the array substrate falls within the orthographic projection of the pixel defining part 71 on the array substrate 10, so as to improve the partition effect of the isolation opening 21 enclosed by the isolation structure 20.

The pixel defining part 71 is provided with a receiving groove 711, which can be formed by a depression on one side of the pixel defining part 71 facing away from the array substrate 10. Optionally, a depression depth of the receiving groove 711 and a depression depth of the pixel opening 72 can be the same or different. Optionally, the receiving groove 711 can pass through the pixel defining part 71.

Optionally, the through hole 22 passes through the receiving groove 711.

Optionally, one or more receiving grooves 711 can be arranged between adjacent two of the pixel openings 72. The isolation structure 20 is arranged in the receiving groove, which can reduce the space occupied by the isolation structure in the thickness direction Z of the display panel, thereby reducing the overall thickness of the display panel.

In some embodiments, referring to FIG. 18, the through hole 22 passes through the first isolation part 23 and the second isolation part 24 so that the first isolation part and the second isolation part are evenly divided into two parts, and a length of the second isolation part 24 in each part in a direction toward the isolation opening 21 is greater than a length of the first isolation part 23 in a direction toward the isolation opening 21. Optionally, the second isolation part 24 and the first isolation part 23 in each part may have a flat surface on one side facing the through hole 22, that is, the inner wall enclosing the through hole 22 is a flat surface, thereby reducing the possibility of the through hole being blocked by the isolation structure 20.

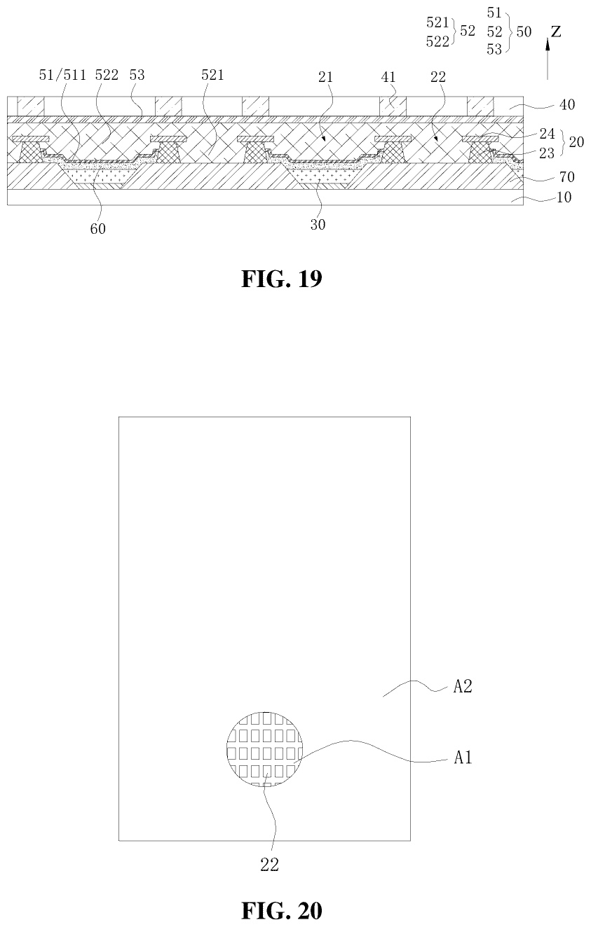

In some embodiments, referring to FIG. 19, two or more first isolation parts 23 and second isolation parts 24 that are stacked are arranged between adjacent isolation openings 21, and a through hole 22 is arranged between the two or more first isolation parts 23 and second isolation parts 24 that are stacked.

In the embodiments of the present application, both sides of the through hole can be a first isolation part 23 and a second isolation part 24 each with a longitudinal cross-section that is larger at the top and smaller at the bottom. This design is conductive to enabling it difficult for the light-emitting material and the electrode material to be connected jointly when they fall into the through hole 22 during the preparation of the light-emitting unit 30 and the first electrode 60, thereby reducing the possibility of the light-emitting material being lit in the through hole 22 and causing abnormal display effects.

In some optional embodiments, the isolation structure 20 is an insulating structure. In other words, the isolation structure 20 can be a pixel definition layer 70, or the isolation structure is part of the pixel definition layer.

In some optional embodiments, referring to FIGS. 19 and 20, the display panel also includes a first display area and a second display area, a light transmittance of the first display area is greater than a light transmittance of the second display area. Optionally, the through hole 22 and the light-emitting unit group E0 are arranged in the first display area. Optionally, the first display area is a photosensitive area A1, and the second display area is a non-photosensitive area A2.

Optionally, the second display area can be arranged around at least part of the first display area.

Optionally, a photosensitive element may be provided in the first display area. Exemplarily, a camera device, a fingerprint recognition device or other photosensitive elements may be provided in the first display area. External light may be projected to the photosensitive element through the through hole 22, so that the photosensitive element can act according to the acquired light.

Optionally, the through hole 22 may be provided in the first display area, or the through hole may be provided in the second display area.

Optionally, the light-emitting unit group E0 may be provided in the first display area, or the light-emitting unit group E0 may be provided in the second display area.

As shown in FIGS. 1 to 3 and 20, an embodiment of the present application provides a display panel that includes a first display area and a second display area, a light transmittance of the first display area is greater than a light transmittance of the second display area, and the display panel further includes an array substrate 10, a light-emitting layer, an isolation structure 20 and a touch layer 40. The light-emitting layer is located on one side of the array substrate 10 and includes a plurality of light-emitting units 30. The isolation structure 20 is located on one side of the array substrate 10 and includes an isolation opening and a through hole 22, where the light-emitting unit 30 is provided in the isolation opening, and the through hole is provided in the first display area. The touch layer 40 includes touch traces 41 arranged on the side of the isolation structure 20 facing away from the array substrate 10. In the first display area, the orthographic projections of the touch traces 41 in the thickness direction Z of the display panel are arranged at least around the through hole 22. In the second display area, the orthographic projections of the touch traces 41 in the thickness direction Z are arranged around the isolation opening 21.

Optionally, as described above, when the display panel includes the first display area and the second display area, the orthographic projections of the touch traces 41 in the first display area in the thickness direction Z are arranged around a part or all of the through hole 22. The orthographic projections of the touch traces 41 in the second display area in the thickness direction Z are arranged around a periphery of the isolation opening 21.

The arrangement of the array substrate 10, the light-emitting layer, the isolation structure 20, and the touch layer 40 is as described in the above-mentioned display panel embodiment, which will not be repeated here.

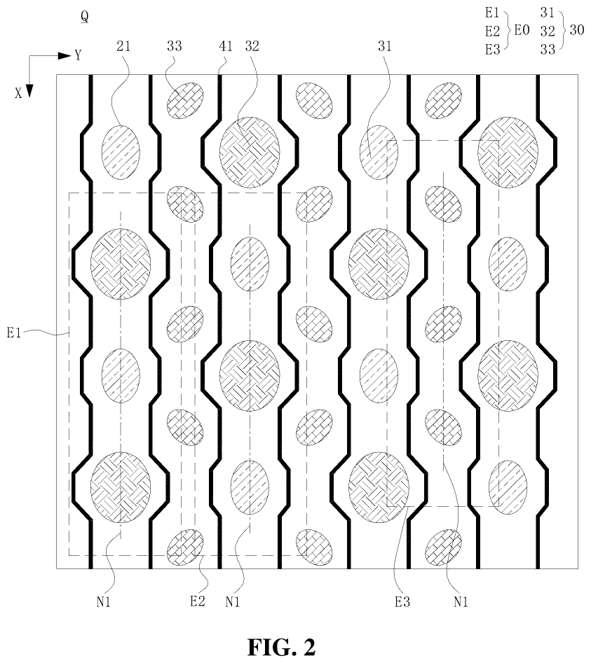

In some optional embodiments, referring to FIG. 2, a plurality of light-emitting units 30 include a plurality of light-emitting unit groups E0, each light-emitting unit group E0 emits light of a single color, the light-emitting unit group includes at least one light-emitting structure arranged in the first direction X, at least parts of the orthographic projections of the touch traces 41 in the thickness direction Z of the display panel are arranged around at least one light-emitting structure, and symmetrically with respect to a first symmetry axis N1 passing through at least one light-emitting structure and parallel to the first direction X intersecting with the thickness direction Z.

The arrangement of the light-emitting unit group E0 and the touch layer 40 is as described in the above display panel embodiment, which will not be repeated here.

As shown in FIG. 1 to FIG. 4, the embodiments of the present application provides a display panel, the display panel includes an array substrate 10, a light-emitting layer, an isolation structure 20 and a touch layer 40. The light-emitting layer is located on one side of the array substrate 10, and the light-emitting layer includes a plurality of light-emitting units 30. The isolation structure 20 is located on one side of the array substrate 10, and the isolation structure includes an isolation opening 21, and the light-emitting unit 30 is arranged in the isolation opening. The touch layer 40 includes a touch trace 41, which is arranged on a side of the isolation structure 20 facing away from the array substrate 10. The orthographic projections of the touch traces 41 in the thickness direction Z of the display panel surround the orthographic projection of at least one isolation opening 21 in the thickness direction Z.

Optionally, as described above, when the display panel includes an isolation opening, a figure of the orthographic projection of the touch trace 41 in the thickness direction Z includes but is not limited to a continuous closed shape and a discontinuous shape. Exemplarily, the figure of the orthographic projection of the touch trace 41 in the thickness direction Z includes a circular ring or a semicircular ring. Optionally, the orthographic projection of the touch trace 41 in the thickness direction Z and the orthographic projection of the isolation structure 20 in the thickness direction Z overlap.

The arrangement of the array substrate 10, the light-emitting layer, the isolation structure 20, and the touch layer 40 is as described in the above-mentioned display panel embodiment, which will not be repeated here.

In the display panel and display device provided in the present application, the touch traces 41 are arranged around the isolation opening 21, thereby reducing the difference in the ranges of light emitted by the light-emitting unit 30 in the isolation opening in different directions, thereby reducing the difference in the luminous brightness at different positions of the light-emitting unit 30 under a wide viewing angle, and reducing the possibility of color shift in displayed images.

In some embodiments, referring to FIGS. 14 and 15, the isolation structure 20 also includes a through hole 22, which is arranged between adjacent two of the isolation openings 21, and the orthographic projections of the touch traces 41 in the thickness direction Z surround the orthographic projection of at least part of the through hole 22 in the thickness direction.

Optionally, the orthographic projections of the through hole and the isolation opening 21 in the thickness direction Z may have a similar figure. Of course, they may have a different figure. Below an example will be taken for illustration in which the figure of the orthographic projection of the through hole 22 in the thickness direction Z is a rectangle or a square, and the figure of the orthographic projection of the isolation opening 21 in the thickness direction Z is a circle.

In the embodiments of the present application, the light transmittance of the display panel is improved by arranging a through hole 22, and the touch traces 41 are arranged around at least part of the through hole 22 to reduce the influence of the touch traces on the light transmittance.

In some optional embodiments, adjacent four of the through holes 22 are arranged around an isolation opening 21.

Exemplarily, two through holes 22 are arranged on both sides of the isolation opening 21 in the first direction X respectively, and two through holes are arranged on both sides of the isolation opening in the second direction Y respectively.

In some optional embodiments, adjacent four of the isolation openings 21 are arranged around a through hole 22.

Exemplarily, two isolation openings 21 are arranged on both sides of the through hole 22 in the first direction X respectively, and two isolation openings are arranged on both sides of the through hole in the second direction Y respectively.

In some embodiments, referring to FIG. 15, the display panel further includes a pixel group, which includes a plurality of light-emitting units 30 of different colors and a plurality of through holes 22 distributed on a periphery of the light-emitting units, in the pixel group, the through holes 22 each include a first through hole 221 and a second through hole 222, and a orthographic projection of the touch conductive part 42 in the thickness direction Z surrounds a periphery of a orthographic projection of the first through hole 221 in the thickness direction Z, and a orthographic projection of a virtual conductive part 43 in the thickness direction Z surrounds a periphery of a orthographic projection of a second through hole 222 in the thickness direction Z.

Optionally, the light-emitting units 30 in the display panel can be arranged in a form of pixel groups. Exemplarily, the pixel groups each includes a plurality of light-emitting units 30 with different colors, and the display panel is arranged in a matrix with the pixel group as a basic unit. Multiple through holes 22 can be arranged in each pixel group, and each through hole is located between adjacent two of the light-emitting units 30.

Optionally, the pixel groups each can include one or more pixel units.

Optionally, the number of the first through holes 221 and the number of the second through holes 222 can be the same or different.

In the embodiments of the present application, a virtual conductive part 43 is provided in each pixel group to balance the parasitic capacitance formed by the touch electrode 44 and other conductive film layers and the difference in the ranges of light emitted by the light-emitting unit 30 at different viewing angles.

In some embodiments, referring to FIG. 15, the light-emitting unit 30 includes a first light-emitting structure 31, a second light-emitting structure 32 and a third light-emitting structure 33, and the first light-emitting structures 31 and second light-emitting structures 32 are alternately distributed on the two opposite sides of the third light-emitting structure in the first direction X, and the second through hole 222 is located between adjacent two of the third light-emitting structures 33, and the first direction X intersects with the thickness direction Z.

Optionally, the colors of the first light-emitting structure 31, the second light-emitting structure 32 and the third light-emitting structure 33 are different.

Optionally, the pixel group may include two third light-emitting structures 33, one first light-emitting structure 31 and one second light-emitting structure 32.

Optionally, the third light-emitting structure 33 includes a first side and a second side in the first direction X, on the first side, the first light-emitting structures 31 and the second light-emitting structures 32 are alternately distributed, and on the second side, the first light-emitting structures 31 and the second light-emitting structures 32 are alternately distributed.

The second through hole 222 is located between adjacent two of the light-emitting units 30. In other words, the second through hole 222 can be located at a center of the pixel group. In some examples, an orthographic projection of a touch electrode 44 in the thickness direction Z covers the orthographic projections of multiple pixel groups in the thickness direction Z. The second through hole 222 is arranged at a center of the pixel group to reduce the interference of the virtual conductive part 43 on the touch capacitance formed between the two touch electrodes 44.

In some embodiments, referring to FIG. 19, the display panel also includes an encapsulation layer 50, which is located between the light-emitting layer and the touch layer 40. The encapsulation layer 50 includes a first encapsulation layer 51 and a second encapsulation layer 52 which are stacked. The first encapsulation layer includes a plurality of first encapsulation parts 511 arranged in the isolation openings 21 respectively, and the second encapsulation layer 52 includes a plurality of second encapsulation parts 521 arranged in the through holes 22 respectively and a second encapsulation body 522 located between the first encapsulation layer 51 and the touch layer 40.

The encapsulation layer is located between the light-emitting layer and the touch layer 40, that is, located on the light-emitting surface side of the light-emitting unit 30. The first encapsulation layer 51 can play a role in encapsulation and protection for the light-emitting unit. Due to the presence of the isolation structure 20, the prepared first encapsulation layer 51 may have a plurality of first encapsulation parts 511 corresponding to the light-emitting unit 30 and located in the isolation opening 21, and each first encapsulation part may play a role of independent encapsulation for each light-emitting unit 30, thereby improving the encapsulation protection effect of the light-emitting units.

The material composition of the first encapsulation layer 51 is not limited in the embodiments of the present application. Exemplarily, the first encapsulation layer 51 includes an inorganic material.

Each second encapsulation part 521 may be located in the through hole 22, and may play a filling role, thereby improving the flatness of the display panel in sequence.

In some examples, the encapsulation layer 50 also includes a third encapsulation layer 53 located on a side of the second encapsulation layer 52 facing away from the first encapsulation layer 51, and the first encapsulation layer, the second encapsulation layer 52 and the third encapsulation layer may jointly form a thin film encapsulation structure, thereby further reducing the risk of water and oxygen etc. intruding into the light-emitting unit 30 and improving the reliability of the display panel. The material composition of the second encapsulation layer 52 and the third encapsulation layer 53 is not limited in the embodiments of the present application. Optionally, the first encapsulation layer 51 and the third encapsulation layer 53 both include inorganic materials, and the second encapsulation layer 52 includes organic materials, so that the first encapsulation layer 51 and the second encapsulation layer 52 can limit the second encapsulation layer 50 to a certain extent, thereby improving the structural reliability.

Unlike the first encapsulation layer 51, the second encapsulation body 522 and the third encapsulation layer 53 may be in a whole-surface structure, that is, the orthographic projections of the second encapsulation body 522 and the third encapsulation layer on the array substrate 10 can simultaneously cover the orthographic projections of multiple light-emitting units 30 on the array substrate 10.

In the second aspect, the embodiments of the present application also provide a display device, including any one of the display panels described above.

The display device in the embodiments of the present application includes but is not limited to mobile phones, personal digital assistants (PDAs), tablet computers, e-books, televisions, access control, smart fixed phones, consoles and other devices with display functions.

What is claimed is:

1. A display panel, comprising:
an array substrate;
a light-emitting layer located on a side of the array substrate and comprising a plurality of light-emitting units, the light-emitting units comprising a plurality of light-emitting unit groups, and each of the light-emitting unit groups emitting light of a single color and including at least one light-emitting structure arranged in a first direction;
an isolation structure located on a side of the array substrate and comprising an isolation opening, the light-emitting unit is arranged in the isolation opening; and
a touch layer comprising touch traces that are arranged on a side of the isolation structure facing away from the array substrate, wherein at least parts of orthographic projections of the touch traces in a thickness direction of the display panel are arranged around the at least one light-emitting structure and symmetrically with respect to a first symmetry axis passing through a centroid of the at least one light-emitting structure and parallel to the first direction intersecting with the thickness direction.

2. The display panel according to claim 1, wherein the at least one light-emitting structure comprises a plurality of light-emitting structures, in the light-emitting unit group, a plurality of the light-emitting structures sequentially arranged in the first direction;
at least parts of the orthographic projections of the touch traces in the thickness direction are arranged around the plurality of light-emitting structures and symmetrically with respect to the first symmetry axis passing through the plurality of light-emitting structures; and
the touch traces form a grid-shaped touch pattern including a plurality of grids, each of grids corresponds to at least one of the light-emitting structures, and parts of the touch pattern surrounding the at least one light-emitting structure are arranged symmetrically at least with respect to the first symmetry axis.

3. The display panel according to claim 2, wherein in the light-emitting unit group, the at least one light-emitting structure comprises 2N+1 light-emitting structures, and the orthographic projections of the touch traces in the thickness direction are symmetrically arranged with respect to a second symmetry axis parallel to a second direction and passing through a centroid of the N+1th light-emitting structure, where N≥0, and the second direction and the first direction are both perpendicular to the thickness direction;
in a case of N=0, in the light-emitting unit group, the at least one light-emitting structure comprises one light-emitting structure, and the orthographic projections of the touch traces in the thickness direction are symmetrically arranged with respect to the second symmetry axis parallel to the second direction and passing through the centroid of the light-emitting structure;
in a case of N=1, in the light-emitting unit group, the at least one light-emitting structure comprises three light-emitting structures, and the orthographic projections of the touch traces in the thickness direction are symmetrically arranged with respect to the second symmetry axis passing through a centroid of the second light-emitting structure in the first direction.

4. The display panel according to claim 2, wherein in the light-emitting unit group, the at least one light-emitting structure comprises 2N light-emitting structures, and the orthographic projections of the touch traces in the thickness direction are symmetrically arranged with respect to a third symmetry axis parallel to a second direction and located between the Nth light-emitting structure and the N+1th light-emitting structure, where N>0, and the second direction and the first direction are both perpendicular to the thickness direction;
in a case of N=1, in the light-emitting unit group, the at least one light-emitting structure comprises two light-emitting structures, and the orthographic projections of the touch traces in the thickness direction are symmetrically arranged with respect to the third symmetry axis located in the middle of the first light-emitting structure and the second light-emitting structure.

5. The display panel according to claim 2, wherein at least parts of the orthographic projections of the touch traces in the thickness direction are arranged around the plurality of light-emitting structures and symmetrically with respect to the first symmetry axis parallel to the first direction and passing through centroids of the plurality of light-emitting structures; no touch trace is provided on a side of the light-emitting structure located at one end of the light-emitting unit group in the first direction in the light-emitting unit group which side is away from the light-emitting structure at the other end of the light-emitting unit group in the first direction, and no touch trace is provided on a side of the light-emitting structure located at the other end of the light-emitting unit group in the first direction in the light-emitting unit group which side is away from the light-emitting structure at the one end of the light-emitting unit group in the first direction.

6. The display panel according to claim 2, wherein the orthographic projections of the touch traces in the thickness direction enclose the isolation opening and are symmetrically arranged with respect to both the first symmetry axis and the second symmetry axis that is parallel to the second direction intersecting with the first direction.

7. The display panel according to claim 2, wherein the isolation structure further comprises a through hole that is provided between at least adjacent two of the isolation openings, and the orthographic projections of the touch traces in the thickness direction enclose the through hole.

8. The display panel according to claim 7, wherein the light-emitting unit groups comprise a first light-emitting structure group emitting light of a first color, a second light-emitting structure group emitting light of a second color, and a third light-emitting structure group emitting light of a third color, the first light-emitting structure group including at least one first light-emitting structure, the second light-emitting structure group including at least one second light-emitting structure, the third light-emitting structure group including at least one third light-emitting structure; the light of a first color, the light of a second color, and the light of a third color are different from one another;
the first light-emitting structures and the second light-emitting structures are alternately arranged in the first direction to form a first light-emitting column, and the third light-emitting structures are sequentially arranged in the first direction to form a second light-emitting column, the first light-emitting column and the second light-emitting column are alternately arranged in the second direction; the first light-emitting structures in one of two adjacent columns of the first light-emitting columns and the second light-emitting structures in the other of the two adjacent columns of the first light-emitting columns are sequentially arranged in the second direction;
the third light-emitting structure in the second light-emitting column is correspondingly located between the first light-emitting structure and the second light-emitting structure that are adjacent in the first light-emitting column;
the light-emitting layer comprises a plurality of pixel units arranged repeatedly, the pixel units taking the form of a plurality of virtual quadrilaterals arranged in rows and columns, two vertices of the virtual quadrilateral opposite in the first direction coinciding with centers of the first light-emitting structure and the second light-emitting structure respectively, and the other two vertices opposite in the second direction coinciding with centers of the two third light-emitting structures respectively, and the first direction and the second direction are arranged perpendicularly.

9. The display panel according to claim 8, wherein the through hole is provided between adjacent two of the isolation openings in at least one of the first light-emitting column or the second light-emitting column;
the through hole is provided in one of two adjacent columns of the first light-emitting columns;
the light-emitting units comprise a first type of light-emitting column, a second type of light-emitting column, and a third type of light-emitting column, and the through holes each are provided between adjacent two of the isolation openings in the first type of light-emitting column and the second type of light-emitting column;
in the first type of light-emitting column, the isolation opening is surrounded by the orthographic projections of the touch traces in the thickness direction, and the through hole is surrounded by the orthographic projections of the touch traces in the thickness direction;
in the second type of light-emitting column, the isolation opening and the through hole are jointly surrounded by the orthographic projections of the touch traces in the thickness direction; and
in the third type of light-emitting column, a plurality of the isolation openings are jointly surrounded by the orthographic projections of the touch traces in the thickness direction.

10. The display panel according to claim 8, wherein the first light-emitting structure, the second light-emitting structure and the third light-emitting structure each are in a rectangular shape; in the first light-emitting column, vertex angles of the first light-emitting structure and the second light-emitting structure are arranged oppositely in the first direction, and in the second light-emitting column, vertex angles of adjacent two of the third light-emitting structures are arranged oppositely in the first direction; and
wherein the through hole is arranged between the first light-emitting structure and the second light-emitting structure that are adjacent in the first light-emitting column; or, the through hole is arranged between adjacent two of the third light-emitting structures in the second light-emitting column;
the touch traces surrounding the through hole are in a rectangular shape, and vertex angles of any one of the first light-emitting structure, the second light-emitting structure and the third light-emitting structure are arranged oppositely to opposite sides of the touch traces surrounding the through hole.

11. The display panel according to claim 8, wherein the orthographic projections of the touch traces in the thickness direction are arranged around a periphery of the isolation opening and a periphery of the through hole, and the touch trace includes a first section and a second section, orthographic projections of the first section and the second section in the thickness direction are arranged to jointly surround the through hole between adjacent two of the isolation openings, a center line connecting adjacent two of the light-emitting structures is perpendicular to the first section and parallel to the second section;
the light-emitting structures are arranged in columns in the first direction and in rows in the second direction, and in one column, a center line connecting adjacent two of the light-emitting structures is perpendicular to the first section and parallel to the second section, and a center line connecting one of the first light-emitting structure and the second light-emitting structure in the first light-emitting column with the third light-emitting structure in the second light-emitting column is perpendicular to the touch trace between the first light-emitting structure and the third light-emitting structure or the touch trace between the second light-emitting structure and the third light-emitting structure.

12. The display panel according to claim 7, wherein a spacing distance between one of adjacent two of the isolation openings and the through hole is equal to a spacing distance between the other one of adjacent two of the isolation openings and the through hole, and the orthographic projections of the touch traces in the thickness direction are arranged around a periphery of the through hole.

13. The display panel according to claim 8, wherein the isolation structure comprises a first isolation part and a second isolation part located on a side of the first isolation part away from the substrate, the second isolation parts enclose and form isolation sub-openings, the first light-emitting structure and the second light-emitting structure are arranged adjacent to each other, the orthographic projections of the touch traces in the thickness direction each is located between adjacent of the first light-emitting structure and the second light-emitting structure, and a spacing distance between an inner wall of the isolation sub-opening located on a side of the first light-emitting structure close to the second light-emitting structure and the orthographic projection of the touch trace in the thickness direction is equal to a spacing distance between an inner wall of the isolation sub-opening located on a side of the second light-emitting structure close to the first light-emitting structure and the orthographic projection of the touch trace in the thickness direction.

14. The display panel according to claim 7, wherein the touch trace comprises a touch conductive part and a virtual conductive part, a plurality of the touch conductive parts are electrically connected with each other to form a touch electrode, the virtual conductive part is insulated from the touch conductive part;
the virtual conductive part is arranged in the touch electrode;
wherein the touch conductive part comprises a first sub-part and a second sub-part, the first sub-part is located on at least one side of the isolation opening, and an orthographic projection of the second sub-part in the thickness direction surrounds an orthographic projection of the through hole in the thickness direction and is connected to the first sub-part;
orthographic projections of the first sub-part and the second sub-part in the thickness direction are arranged to jointly surround an orthographic projection of the isolation opening in the thickness direction;
the virtual conductive part comprises a third sub-part and a fourth sub-part, the fourth sub-part is arranged around at least one of the through holes, the third sub-part is connected to the fourth sub-part and extends away from an inner part of the fourth sub-part;
the third sub-part is located on at least one side of the isolation opening;
a shape of an orthographic projection of the fourth sub-part in the thickness direction comprises a rectangle;
the fourth sub-part connects a plurality of the third sub-parts arranged at intervals.

15. The display panel according to claim 7, wherein the isolation structure comprises a first isolation part and a second isolation part located on a side of the first isolation part away from the substrate, an orthographic projection of the first isolation part on the substrate is located within an orthographic projection of the second isolation part on the substrate;
the display panel further comprises a first electrode located on a side of the light-emitting layer away from the array substrate, the first isolation part is a conductive structure, and the first electrode is electrically connected to the first isolation part;
the isolation structure further comprises a third isolation part, and the first isolation part is located between the third isolation part and the second isolation part;
the display panel further comprises pixel definition layers arranged on the array substrate, the pixel definition layers comprise pixel defining parts and pixel openings defined by the pixel defining parts, the pixel openings are connected with the isolation openings to accommodate the light-emitting units, and an orthographic projection of an inner wall of each of the pixel openings on the substrate is located within an orthographic projection of an inner wall of each of the isolation openings on the array substrate;
the isolation structure is arranged on a side of the pixel defining part away from the array substrate, or the pixel defining part is provided with a receiving groove, and the isolation structure is arranged in the receiving groove;
the through hole passes through the first isolation part and the second isolation part;
two or more first isolation parts and second isolation parts that are stacked are arranged between adjacent ones of the isolation openings, and the through hole is arranged between the two or more first isolation parts and second isolation parts that are stacked;
the isolation structure is an insulating structure.

16. The display panel according to claim 7, wherein the display panel further comprises a first display area and a second display area, a light transmittance of the first display area is greater than a light transmittance of the second display area;
the through hole and the light-emitting unit groups are arranged in the first display area;
the first display area is a photosensitive area, and the second display area is a non-photosensitive area.

17. A display panel, comprising a first display area and a second display area, a light transmittance of the first display area is greater than a light transmittance of the second display area, and the display panel further comprising:
an array substrate;
a light-emitting layer located on a side of the array substrate and comprising a plurality of light-emitting units;
an isolation structure located on a side of the array substrate and comprising a plurality of isolation openings and a plurality of through holes, each of the light-emitting units being arranged in the corresponding one of the isolation openings, and the through holes being arranged in the first display area; and
a touch layer comprising touch traces that are arranged on a side of the isolation structure facing away from the array substrate, wherein in the first display area, orthographic projections of the touch traces in a thickness direction of the display panel are arranged at least around the through hole; and in the second display area, orthographic projections of the touch traces in the thickness direction are arranged around the corresponding one of the isolation openings.

18. The display panel according to claim 17, wherein the plurality of light-emitting units comprise a plurality of light-emitting unit groups, each of the light-emitting unit groups emitting light of a single color and including at least one light-emitting structure arranged in a first direction, and at least parts of the orthographic projections of the touch traces in the thickness direction of the display panel are arranged around the at least one light-emitting structure and symmetrically with respect to a first symmetry axis passing through the at least one light-emitting structure and parallel to the first direction intersecting with the thickness direction.

19. A display panel, comprising:
an array substrate;
a light-emitting layer located on a side of the array substrate and comprising a plurality of light-emitting units;
an isolation structure located on a side of the array substrate and comprising isolation openings, each of the light-emitting units is arranged in the corresponding one of the isolation openings; and
a touch layer comprising touch traces that are arranged on a side of the isolation structure facing away from the array substrate, wherein orthographic projections of the touch traces in a thickness direction of the display panel surround an orthographic projection of at least one of the isolation openings in the thickness direction.

20. The display panel according to claim 19, wherein the isolation structure further comprises a through hole arranged between adjacent two of the isolation openings, the orthographic projections of the touch traces in the thickness direction surround an orthographic projection of at least part of the through hole in the thickness direction;
adjacent four of the through holes are arranged around one of the isolation openings;
adjacent four of the isolation openings are arranged around one of the through holes;
the light-emitting units arranged in at least of the adjacent four isolation openings have different colors;
the touch trace comprises a touch conductive part and a virtual conductive part, a plurality of the touch conductive parts are electrically connected with each other to form a touch electrode, and the virtual conductive part is insulated from the touch conductive part; and
the virtual conductive part is arranged in the touch electrode;
wherein the touch conductive part comprises a first sub-part and a second sub-part, the first sub-part is located on at least one side of the corresponding one of the isolation openings, and an orthographic projection of the second sub-part in the thickness direction surrounds an orthographic projection of the through hole in the thickness direction and is connected to the first sub-part;
orthographic projections of the first sub-part and the second sub-part in the thickness direction are arranged to jointly surround an orthographic projection of the corresponding one of the isolation openings in the thickness direction;
the virtual conductive part comprises a third sub-part and a fourth sub-part, the fourth sub-part is arranged around at least one of the through holes, the third sub-part is connected to the fourth sub-part and extends away from an inner part of the fourth sub-part;
the third sub-part is located on at least one side of the corresponding one of the isolation openings;
a shape of an orthographic projection of the fourth sub-part in the thickness direction comprises a rectangle;
the fourth sub-part connects a plurality of third sub-parts arranged at intervals;
the display panel further comprises a pixel group that comprises a plurality of light-emitting units of different colors and a plurality of through holes distributed on a periphery of the light-emitting units,
in the pixel group, the through holes comprise a first through hole and a second through hole, and an orthographic projection of the touch conductive part in the thickness direction encloses a periphery of an orthographic projection of the first through hole in the thickness direction, and an orthographic projection of the virtual conductive part in the thickness direction encloses a periphery of an orthographic projection of the second through hole in the thickness direction; and
wherein the light-emitting units comprise a first light-emitting structure, a second light-emitting structure and a third light-emitting structure, the first light-emitting structures and the second light-emitting structures are distributed alternately on each of two opposite sides of the third light-emitting structure in a first direction; the second through hole is located between adjacent two of the third light-emitting structures; and the first direction intersects with the thickness direction.
